(19) United States
(12) Patent Application Publication
(10) Pub. No.: US 2025/0071994 A1
(43) Pub. Date: Feb. 27, 2025

(54) SEMICONDUCTOR DEVICES

(71) Applicant: SAMSUNG ELECTRONICS CO., LTD., Suwon-si (KR)

(72) Inventors: Kohji Kanamori, Suwon-si (KR); Seogoo Kang, Suwon-si (KR); Kyungdong Kim, Suwon-si (KR); Seunghyun Lee, Suwon-si (KR); Junghoon Jun, Suwon-si (KR); Jeehoon Han, Suwon-si (KR); Taeyoon Hong, Suwon-si (KR)

(21) Appl. No.: 18/767,830

(22) Filed: Jul. 9, 2024

(30) Foreign Application Priority Data
Aug. 22, 2023 (KR) 10-2023-0109882

(51) Int. Cl. H10B 43/27; H10B 43/10; H10B 43/35; H10B 43/40

(52) U.S. Cl. CPC H10B 43/27; H10B 43/10; H10B 43/35; H10B 43/40

(57) ABSTRACT

A semiconductor device includes a gate electrode structure, a memory channel structure, and a first contact plug. The gate electrode structure is disposed on a substrate, and includes gate electrodes spaced apart from each other in a first direction substantially perpendicular to an upper surface of the substrate. Each of the gate electrode extends in a second direction substantially parallel to the upper surface of the substrate. The memory channel structure extends through the gate electrode structure on the substrate. The first contact plug extends in the first direction on the substrate through and contacting a corresponding one of the gate electrodes, and a portion of a sidewall of the first contact plug at substantially the same level as the corresponding one of the gate electrodes is not surrounded by the corresponding one of the gate electrodes.

### CROSS-REFERENCE TO RELATED APPLICATION

This application claims priority under 35 U.S.C. § 119 to Korean Patent Application No. 10-2023-0109882 filed on Aug. 22, 2023 in the Korean Intellectual Property Office, the disclosure of which is hereby incorporated by reference in its entirety.

### BACKGROUND

In an electronic system requiring data storage, a high capacity semiconductor device that may store high capacity data is desirable. Thus, a method of increasing the data storage capacity of the semiconductor device has been studied. For example, a semiconductor device including memory cells that may be 3-dimensionally stacked has been suggested.

Research on a method for effectively arranging contact plugs that transfer electrical signals to the memory cells in the semiconductor device is required.

### SUMMARY

In general, in some aspects, the present disclosure is directed toward a semiconductor device having improved electrical characteristics.

According to some implementations, the present disclosure is directed to a semiconductor device that includes a gate electrode structure, a memory channel structure and a first contact plug. The gate electrode structure may be disposed on a substrate, and may include gate electrodes spaced apart from each other in a first direction substantially perpendicular to an upper surface of the substrate. Each of the gate electrode may extend in a second direction substantially parallel to the upper surface of the substrate. The memory channel structure may extend through the gate electrode structure on the substrate. The first contact plug may extend in the first direction on the substrate. The first contact plug may extend through and contact a corresponding one of the gate electrodes, and a portion of a sidewall of the first contact plug at substantially the same level as the corresponding one of the gate electrodes may not be surrounded by the corresponding one of the gate electrodes.

According to some implementations, the present disclosure is directed to a semiconductor device that includes a gate electrode structure, insulation patterns, a memory channel structure and a contact plug. The gate electrode structure may be disposed on a substrate, and may include gate electrodes spaced apart from each other in a first direction substantially perpendicular to an upper surface of the substrate. Each of the gate electrode may extend in a second direction substantially parallel to the upper surface of the substrate. The insulation patterns may be disposed at substantially the same levels as the gate electrodes, respectively, and may be adjacent to sidewalls of end portions in the second direction of the gate electrodes, respectively. The memory channel structure may extend through the gate electrode structure on the substrate. The contact plug may extend in the first direction on the substrate, and may extend through and contact at least a portion of a corresponding one of the gate electrodes and ones of the insulation patterns at respective levels lower than a level of the corresponding one of the gate electrodes. An end portion in the second direction of each of the insulation patterns may include a sidewall having a U shape in a plan view.

According to some implementations, the present disclosure is directed to a semiconductor device that includes a lower circuit pattern, a common source plate (CSP), a gate electrode structure, a memory channel structure, a first insulation pattern, second insulation patterns and a contact plug. The lower circuit pattern may be disposed on a substrate including a first region and a second region. The CSP may be disposed over the lower circuit pattern. The gate electrode structure may be disposed on the CSP, and may include gate electrodes spaced apart from each other in a first direction substantially perpendicular to an upper surface of the substrate. Each of the gate electrode may extend in a second direction substantially parallel to the upper surface of the substrate. The memory channel structure may be disposed on the CSP, and may extend through the gate electrode structure on the first region of the substrate. The first insulation pattern may be disposed on the CSP, and may extend through the gate electrode structure in the second direction on the second region of the substrate. The second insulation patterns may be disposed at substantially the same levels as the gate electrodes, respectively, and may be adjacent to sidewalls of end portions in the second direction of the gate electrodes, respectively. The contact plug may extend in the first direction on the second region of the substrate, and may extend through and contacting a corresponding one of the gate electrodes. A portion of a sidewall of the contact plug at substantially the same level as the corresponding one of the gate electrodes may not be surrounded by the corresponding one of the gate electrodes.

According to some implementations, the present disclosure is directed to contact plugs that are electrically connected to the gate electrodes at a plurality of levels, respectively, that may be electrically insulated from undesired gate electrodes and electrically connected to desired gate electrodes having enhanced electrical characteristics.

### BRIEF DESCRIPTION OF THE DRAWINGS

Example implementations will be more clearly understood from the following detailed description, taken in conjunction with the accompanying drawings.

FIGS. 1 to 6 are plan views and cross-sectional views illustrating an example of a semiconductor device in accordance with some implementations.

FIGS. 7 to 34 are plan views and cross-sectional views illustrating an example of a method of manufacturing a semiconductor device in accordance with some implementations.

FIGS. 35 to 38 are a plan view and cross-sectional views illustrating an example of a semiconductor device in accordance with some implementations.

FIGS. 39 to 50 are plan views and cross-sectional views illustrating an example of a method of manufacturing a semiconductor device in accordance with some implementations.

FIG. 51 is a cross-sectional view illustrating an example of a semiconductor device in accordance with some implementations.

FIG. 52 is a cross-sectional view illustrating an example of a semiconductor device in accordance with some implementations.

### DETAILED DESCRIPTION

Hereinafter, example implementations will be explained in detail with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Accordingly, “first”, “second” and/or “third” may be used selectively or interchangeably for each material, layer, region, electrode, pad, pattern, structure or process respectively.

In the present disclosure, a vertical direction substantially perpendicular to an upper surface of a first substrate may be referred to as a first direction D1, and two directions crossing each other among horizontal directions substantially parallel to the upper surface of the first substrate may be referred to as second and third directions D2 and D3, respectively. In some implementations, the second and third directions D2 and D3 may be substantially perpendicular to each other.

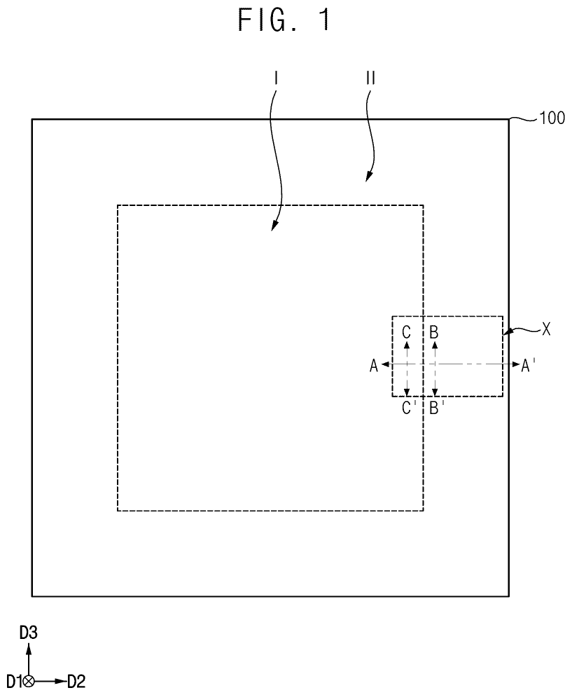

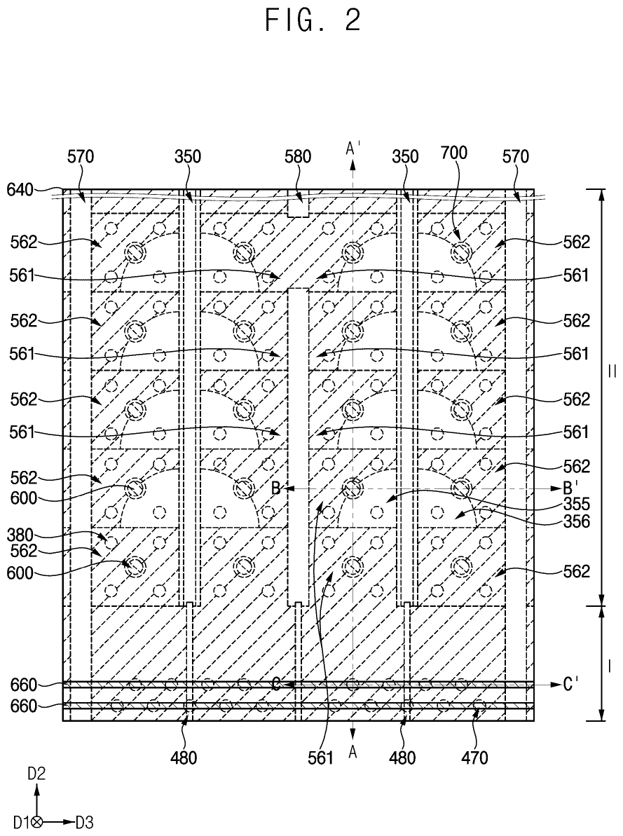

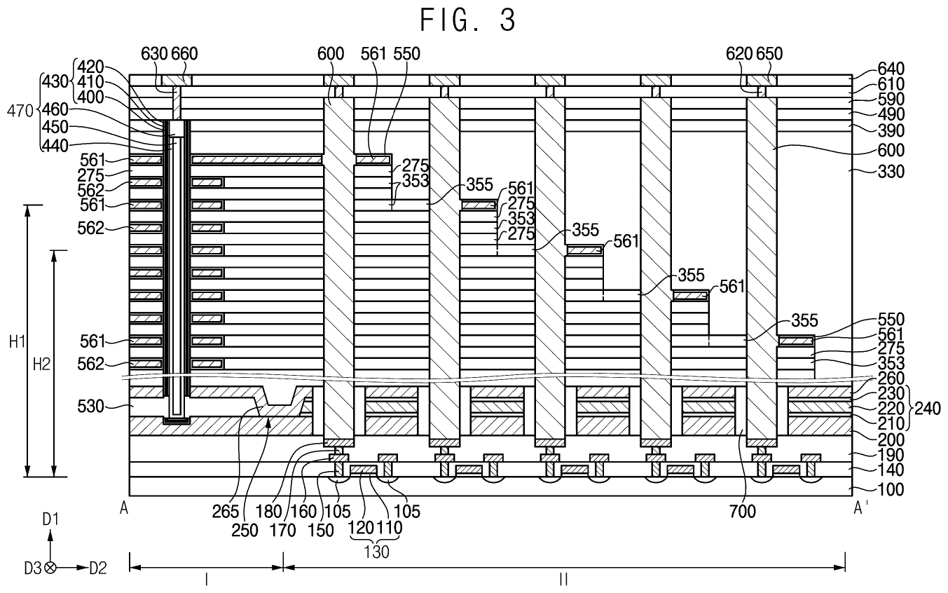

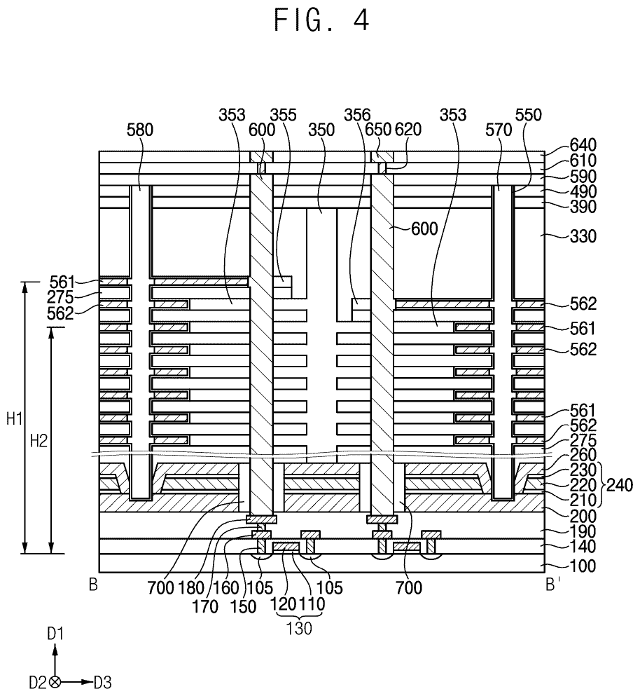

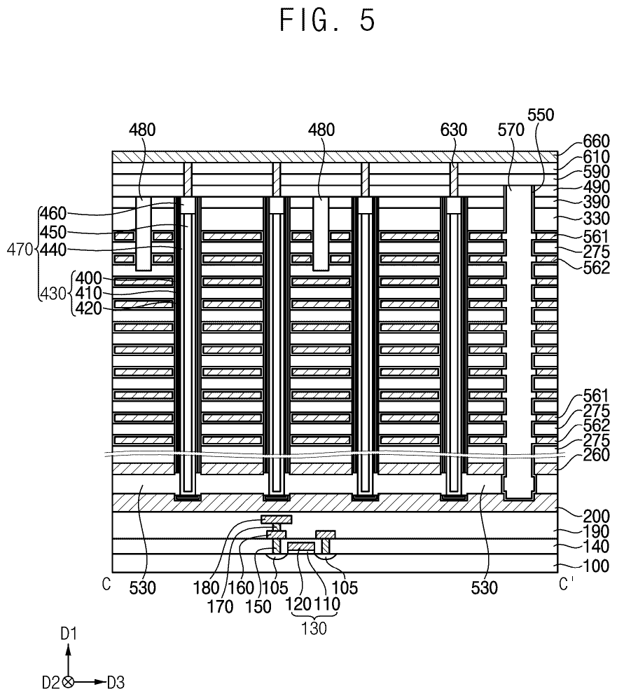

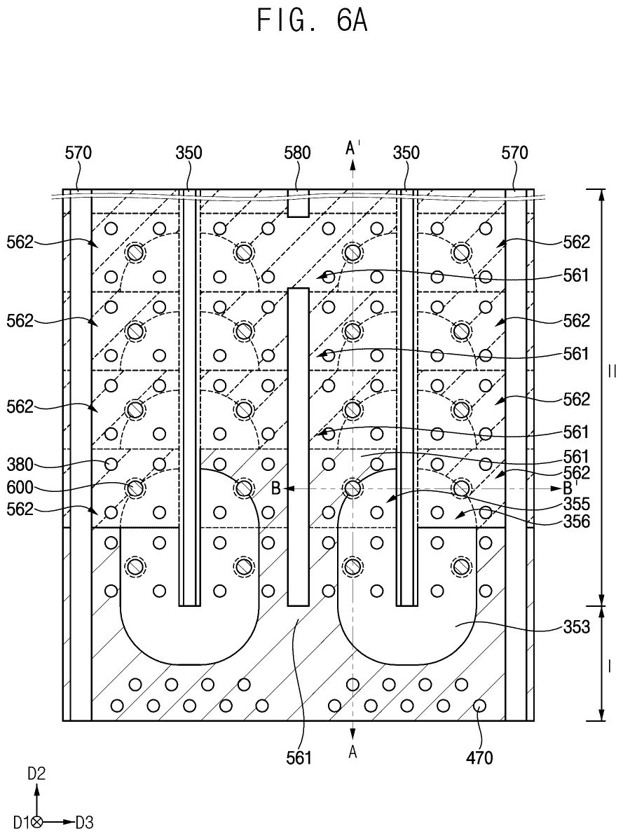

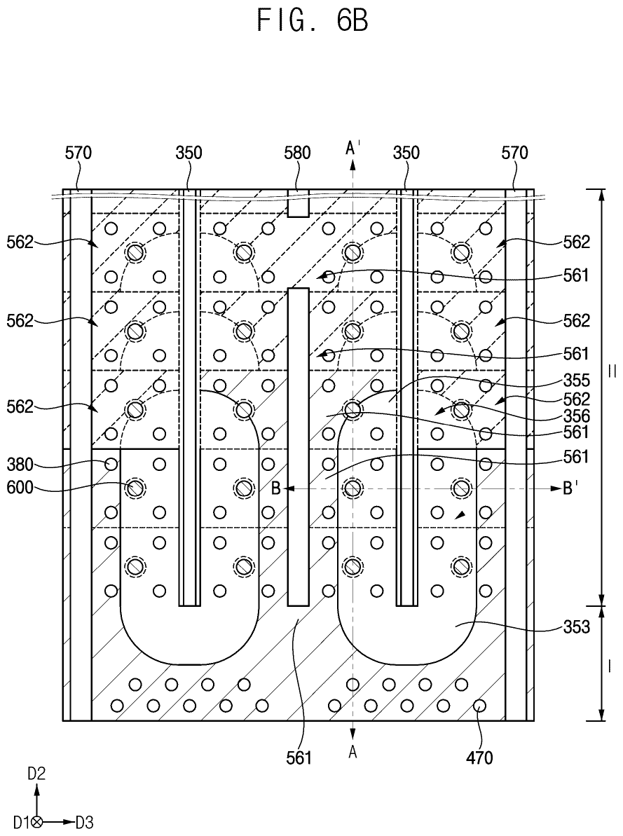

FIGS. 1 to 6 are plan views and cross-sectional views illustrating an example of a semiconductor device in accordance with some implementations. Specifically, FIGS. 1 and 2 are the plan views, FIG. 3 is a vertical cross-sectional view taken along line A-A′ of FIG. 2, FIG. 4 is a vertical cross-sectional view taken along line B-B′ of FIG. 2, FIG. 5 is a vertical cross-sectional view taken along line C-C′ of FIG. 2, FIG. 6A is a horizontal cross-sectional view at a first height H1 of FIGS. 3 and 4, and FIG. 6B is a horizontal cross-sectional view at a second height H2 of FIGS. 3 and 4. FIGS. 2 to 6 show region X in FIG. 1. FIG. 2 shows a fourth wiring 660 among upper wirings in order to avoid the complexity of the drawing.

In FIGS. 1 to 6, a semiconductor device may include a lower circuit pattern, a common source plate (CSP) 200, a gate electrode structure, first to sixth insulation patterns 700, 275, 350, 353, 355 and 356, a memory channel structure 470, a support structure 380, first to third division patterns 480, 570 and 580, first and second contact plugs 150 and 600, first to third vias 170, 620 and 630, and first to fourth wirings 160, 180, 650 and 660 on a first substrate 100. The semiconductor device may further include a support layer 260, a support pattern 265, a sacrificial layer structure 240, a channel connection pattern 530, a second blocking pattern 550, and first to eighth insulating interlayers 140, 190, 330, 390, 490, 590, 610 and 640.

The first substrate 100 may include a semiconductor material, e.g., silicon, germanium, silicon-germanium, etc., or a III-V group compound semiconductor, e.g., GaP, GaAs, GaSb, etc. In some implementations, the first substrate 100 may be a silicon-on-insulator (SOI) substrate or a germanium-on-insulator (GOI) substrate.

The first substrate 100 may include a first region I and a second region II surrounding the first region I. In some implementations, the first region I may be a cell array region, the second region II may be a pad region or an extension region, and the first and second. The first and second regions I and II of the first substrate 100 may collectively form a cell region.

In some implementations, memory cells, each of which includes a gate electrode, a channel, and a charge storage structure, may be formed on the first region I of the first substrate 100, and contact plugs for transferring electrical signals to the memory cells and pads of the gate electrodes contacting the contact plugs may be formed on the second region II of the first substrate 100. FIG. 1 shows that the second region II of the first substrate 100 entirely surrounds the first region I of the first substrate 100, however, the present disclosure may not be limited thereto. For example, the second region II of the first substrate 100 may be formed only at opposite sides of the first region I of the first substrate 100 in the second direction D2.

The first substrate 100 may further include a third region surrounding the second region II, and circuit patterns for applying electrical signals to the memory cells through the contact plugs may be formed on the third region of the first substrate 100.

In some implementations, the semiconductor device may have a cell over periphery (COP) structure. That is, the lower circuit pattern may be disposed on the first substrate 100, and the memory cells, upper contact plugs and an upper circuit pattern may be disposed over the lower circuit pattern. The lower circuit pattern may include, e.g., transistors, lower contact plugs, lower wirings, lower vias, etc.

For example, the transistor may include a lower gate structure 130 on the first substrate 100, and impurity regions 105 at upper portions, respectively, of the first substrate 100 adjacent to the lower gate structure 130. The lower gate structure 130 may include a lower gate insulation pattern 110 and a lower gate electrode 120 sequentially stacked on the first substrate 100. The lower gate insulation pattern 110 may include an oxide, e.g., silicon oxide, and the lower gate electrode 120 may include a conductive material, e.g., a metal, a metal nitride, a metal silicide, doped polysilicon, etc.

The first insulating interlayer 140 may be disposed on the first substrate 100, and may cover the transistor. The first contact plug 150 may extend through the first insulating interlayer 140, and may contact an upper surface of the impurity region 105. The first wiring 160 may be disposed on the first insulating interlayer 140, and may contact an upper surface of the first contact plug 150. The first via 170 and the second wiring 180 may be sequentially stacked on the first wiring 160. The second insulating interlayer 190 may be disposed on the first insulating interlayer 140, and may cover the first and second wirings 160 and 180 and the first via 170.

Each of the first and second insulating interlayers 140 and 190 may include an oxide, e.g., silicon oxide, and each of the first contact plug 150, the first and second wirings 160 and 180 and the first via 170 may include a conductive material, e.g., a metal, a metal nitride, a metal silicide, etc.

The CSP 200 may be disposed on the second insulating interlayer 190. The CSP 200 may include, e.g., polysilicon doped with n-type or p-type impurities. Alternatively, the CSP 200 may have a multi-layered structure including a first layer containing a metal silicide, e.g., tungsten silicide and a second layer containing a semiconductor material doped with impurities stacked in the first direction D1.

The sacrificial layer structure 240, the channel connection pattern 530, the support layer 260 and the support pattern 265 may be disposed on the CSP 200.

The channel connection pattern 530 may be disposed on the first region I of the first substrate 100, and may include an air gap therein. The sacrificial layer structure 240 may be disposed on the second region II of the first substrate 100.

The support layer 260 may be disposed on the channel connection pattern 530 and the sacrificial layer structure 240, and may also be disposed in a first opening 250 extending through the channel connection pattern 530 and the sacrificial layer structure 240 to expose an upper surface of the CSP 200, which may be referred to as a support pattern 265.

In some implementations, the support pattern 265 may have various layouts in a plan view. For example, a plurality of support patterns 265 may be disposed in each of the second and third directions D2 and D3 on the first region I of the first substrate 100, the support pattern 265 may extend in the third direction D3 on a boundary between the first and second regions I and II of the first substrate 100, and a plurality of support patterns 265, each of which may extend in the second direction D2, may be spaced apart from each other in the third direction D3 on the second region II of the first substrate 100. FIG. 3 shows the support pattern 265 extending in the third direction D3 on the boundary between the first and second regions I and II of the first substrate 100, and FIG. 4 shows the plurality of support patterns 265, each of which extends in the second direction D2, spaced apart from each other in the third direction D3 on the second region II of the first substrate 100.

The channel connection pattern 530 may include polysilicon doped with, e.g., n-type impurities or undoped polysilicon. The sacrificial layer structure 240 may include first, second and third sacrificial layers 210, 220 and 230 sequentially stacked in the first direction D1. The first and third sacrificial layers 210 and 230 may include an oxide, e.g., silicon oxide, and the second sacrificial layer 220 may include a nitride, e.g., silicon nitride. The support layer 260 and the support pattern 265 may include a material having an etching selectivity with respect to the first to third sacrificial layers 210, 220 and 230, e.g., polysilicon doped with n-type impurities.

The first insulation pattern 700 may extend through the CSP 200, the sacrificial layer structure 240 and the support layer 260, and a plurality of first insulation patterns 700 may be spaced apart from each other in the second and third directions D2 and D3 on the second region II of the first substrate 100. The first insulation pattern 700 may include an insulating material, e.g., silicon oxide, silicon nitride, etc.

The gate electrode structure may include first and second gate electrodes 561 and 562, each of which may extend in the second direction D2, at a plurality of levels, respectively, spaced apart from each other in the first direction D1, and the second insulation pattern 275 may be interposed between neighboring ones of the first and second gate electrodes 561 and 562 and between the gate electrode structure and each of the support layer 260 and the support pattern 265. The second insulation pattern 275 may include an oxide, e.g., silicon oxide.

The gate electrode structure may have a staircase shape in which each of the first and second gate electrodes 561 and 562 may form a step layer. Hereinafter, a “step layer” may refer to an entire portion of a structure that may be disposed at the same level, and an end portion of each of the step layers, that is, a portion of each of the step layers not overlapping ones of the step layers above each of the step layers in the first direction D1 may be referred to as a “step.”

In some implementations, the gate electrode structure may include a step layer group that may include a plurality of step layers stacked in the first direction D1, and a plurality of step layer groups may be stacked in the first direction D1. Lengths in the second direction D2 of the step layer groups may increase from a lowermost level toward an uppermost level.

In some implementations, end portions in the second direction D2 on the second region II of the first substrate 100 of the step layers included in each of the step layer groups may form steps, respectively, which may be disposed in the third direction D3. A portion of each of the first and second gate electrodes 561 and 562 corresponding to the step, that is, an end portion in the second direction D2 may be referred to as a pad.

In some implementations, each of the step layer groups may include an even number of step layers, e.g., two steps, four steps, six steps, etc., and each of the step layer groups may include an even number of steps, e.g., two steps, four steps, six steps, etc., disposed in the third direction D3 on the second region II of the first substrate 100. FIG. 2 shows that each of the step layer groups includes two step layers.

Hereinafter, first ones of the step layers in each of the step layer groups that may be disposed at odd-numbered levels from a top may be referred to as a first step layer, while second ones of the step layers in each of the step layer groups that may be disposed at even-numbered levels from a top may be referred to as a second step layer. If each of the step layer groups includes two step layers, an upper step layer may be the first step layer, and a lower step layer may be the second step layer. The first and second step layers include first and second steps, respectively, which may be disposed in the third direction D3. The first gate electrode 561 may correspond to the first step layer in each of the step layer groups, and the second gate electrode 562 may correspond to the second step layer in each of the step layer groups.

In some implementations, the first and second gate electrodes 561 and 562 included in each of the step layer groups may have substantially the same length in the second direction D2, and a thickness in the first direction D1 of each of the first and second gate electrodes 561 and 562 may be substantially constant.

In some implementations, a plurality of gate electrode structures may be spaced apart from each other in the third direction D3. The second division pattern 570, which may extend in the second direction D2 on the first and second regions I and II of the first substrate 100, may be interposed between neighboring ones of the gate structures in the third direction D3 on the CSP 200.

The third division pattern 580 may extend through each of the gate electrode structures in the second direction D2 on the second region II of the first substrate 100. In some implementations, the third division pattern 580 may not continuously extend on the second region II of the first substrate 100, and a plurality of third division patterns 580 may be spaced apart from each other in the second direction D2 on the second region II of the first substrate 100. In some implementation, the third division pattern 580 may continuously extend in the second direction D2 on the second region II of the first substrate 100.

In some implementations, the third insulation pattern 350 may extend through the gate electrode structure in the second direction D2 between the second and third division patterns 570 and 580 on the second region II of the first substrate 100.

Each of the second and third division patterns 570 and 580 and the third insulation pattern 350 may include an oxide, e.g., silicon oxide.

In some implementations, the gate electrode structure may have a symmetrical shape with respect to the third division pattern 580 in the third direction D3.

In some implementations, a sidewall in the third direction D3 of the first step of the first step layer included in each of the step layer groups except for an uppermost one of the step layer groups, that is, a sidewall in the third direction D3 of an end portion in the second direction D2 of the first gate electrode 561 may have a first quadrant shape in a plan view. A sidewall in the third direction D3 of the second step of the second step layer included in each of the step layer groups, that is, a sidewall in the third direction D3 of an end portion in the second direction D2 of the second gate electrode 562 may have a second quadrant shape in a plan view. The first and second quadrant shapes may be symmetrical with respect to the third insulation pattern 350.

In some implementations, the fifth and sixth insulation patterns 355 and 356 may be disposed at substantially the same levels of the first and second gate electrodes 561 and 562, respectively, and may be adjacent to the sidewalls of the first and second gate electrodes 561 and 562, respectively. The fifth and sixth insulation patterns 355 and 356 may have the first and second quadrant shapes in a plan view.

In some implementations, the fourth insulation pattern 353 may be disposed in a second recess, which may be formed by removing a portion of the second step layer in each of the step layer groups that is disposed within a given distance from the third insulation pattern 350, and may be disposed at substantially the same level as the second gate electrode 562 and adjacent to a sidewall of the second gate electrode 562.

Additionally, the fourth insulation pattern 353 may be disposed in the second recesses, which may be formed by removing portions of the first and second step layers in ones of the step layer groups under each of the step layer groups that are disposed within a given distance from the third insulation pattern 350, and may be disposed at substantially the same levels as the first and second gate electrodes 561 and 562, respectively, and adjacent to sidewalls of the first and second gate electrodes 561 and 562, respectively. Accordingly, a plurality of fourth insulation patterns 353 may be spaced apart from each other in the first direction D1.

In some implementations, each of the fourth insulation patterns 353 may have a semi-circular shape or a U shape of which a center is located at an end portion of the third insulation pattern 350 in the second direction D2, on the first region I of the first substrate 100 in a plan view. End portions in the second direction D2 of the fourth insulation patterns 353 disposed in the first direction D1 on the first region I of the first substrate 100 may be aligned with each other in the first direction D1.

In some implementations, lengths in the second direction D2 of the fourth insulation patterns 353 may increase from an uppermost level toward a lowermost level, and lengths in the third direction D3 of the fourth insulation patterns 353, except for opposite end portions thereof, may be substantially constant.

In some implementations, each of the first and second gate electrodes 561 and 562 in the gate electrode structure may serve as one of a ground selection line (GSL), a word line and a string selection line (SSL). Additionally, some of the first and second gate electrodes 561 and 562 may serve as a GIDL gate electrode that may be used for erasing data stored in the memory channel structure 470 using a gate induced drain leakage (GIDL) phenomenon.

Each of the first and second gate electrodes 561 and 562 may include a gate conductive pattern and a gate barrier pattern covering a surface of the gate conductive pattern. The gate conductive pattern may include a metal having a low resistance, e.g., tungsten, titanium, tantalum, platinum, etc., and the gate barrier pattern may include a metal nitride, e.g., titanium nitride, tantalum nitride, etc.

The memory channel structure 470 may be disposed on the first region I of the first substrate 100 to contact the upper surface of the CSP 200, and may extend through the channel connection pattern 530, the gate electrode structure, the second insulation pattern 275 and the third and fourth insulating interlayers 330 and 390. In some implementations, the memory channel structure 470 may include a filling pattern 450, which may extend in the first direction D1 and have a pillar shape, a channel 440, which may be disposed on a sidewall of the filling pattern 450 and have a cup shape, a capping pattern 460 contacting upper surfaces of the channel 440 and the filling pattern 450, and a charge storage structure 430 on an outer sidewall of the channel 440 and a sidewall of the capping pattern 460.

The charge storage structure 430 may include a tunnel insulation pattern 420, a charge storage pattern 410 and a first blocking pattern 400 sequentially stacked in the horizontal direction from the outer sidewall of the channel 440.

In some implementations, a plurality of memory channel structures 470 may be spaced apart from each other in the second and third directions D2 and D3 on the first region I of the first substrate 100 to form a memory channel structure array, and the plurality of memory channel structures 470 included in the memory channel structure array may be connected to each other by the channel connection pattern 530. Specifically, the charge storage structure 430 may not be formed on a portion of the outer wall of each of the channels 440, and the channel connection pattern 530 may contact the outer sidewall of the channels 440 to electrically connect the channels 440 to each other.

The channel 440 may include, e.g., undoped polysilicon, the filling pattern 450 may include an oxide, e.g., silicon oxide, and the capping pattern 460 may include, e.g., doped polysilicon.

The tunnel insulation pattern 420 may include an oxide, e.g., silicon oxide, the charge storage pattern 410 may include a nitride, e.g., silicon nitride, and the first blocking pattern 400 may include an oxide, e.g., silicon oxide.

In some implementations, a plurality of memory blocks, each of which may include the gate electrode structure in an area defined by neighboring ones of the second division patterns 570 in the third direction D3 and the memory channel structures 470 in the area, may be disposed in the third direction D3.

The support structure 380 may be disposed on the second region II of the first substrate 100, and may contact the upper surface of the CSP 200. The support structure 380 may extend through the sacrificial layer structure 240, the gate electrode structure, the second insulation pattern 275, and the third insulating interlayer 330.

In some implementations, first ones of the support structures 380 may extend through the first gate electrode 561 in an uppermost one of the step layer groups, and the second insulation patterns 275 and the fourth insulation patterns 353 thereunder, or may extend through the second gate electrode 562 in the uppermost one of the step layer groups, and the second insulation patterns 275 and the fourth insulation patterns 353 thereunder.

Additionally, second ones of the support structures 380 may extend through the first gate electrode 561 or the second gate electrode 562 in each of the step layer groups under the uppermost one thereof, and the second insulation patterns 275 and the fourth insulation patterns 353 thereunder.

Furthermore, third ones of the support structures 380 may extend through the first gate electrode 561 or the second gate electrode 562 in each of the step layer groups under the uppermost one thereof, the second insulation patterns 275 thereunder, and the first and second gate electrodes 561 and 562 in other ones of the step layer groups that are disposed under the second insulation patterns 275. Fourth ones of the support structures 380 may extend through the fifth insulation pattern 355 or the sixth insulation pattern 356 contacting the first gate electrode 561 or the second gate electrode 562, respectively, in each of the step layer groups, and may also extend through the second insulation layers 270 and the fourth insulation patterns 353 thereunder.

In some implementations, the support structure 380 may include, e.g. polysilicon. In some implementations, the supper structure 380 may have substantially the same structure as the memory channel structure 470. However, the support structure 380 may not be connected to a wiring structure including contact plugs, vias, wirings, etc., unlike the memory channel structure 470.

The second blocking pattern 550 may cover upper and lower surfaces and a sidewall facing the memory channel structure 470 and the support structure 380 of each of the first and second gate electrodes 561 and 562. The second blocking pattern 550 may include a metal oxide, e.g., aluminum oxide, hafnium oxide, etc.

The third insulating interlayer 330 may be disposed on the CSP 200, and may cover sidewalls of the gate electrode structure and the second insulation pattern 275. The fourth and fifth insulating interlayers 390 and 490 may be stacked on the third insulating interlayer 330 and the second insulation pattern 275.

The first division pattern 480 may be disposed on the first region I of the first substrate 100, and may extend through upper portions of some of the memory channel structure 470. Additionally, the first division pattern 480 may extend through the third and fourth insulating interlayers 330 and 390, the first and second gate electrodes 561 and 562 included in the uppermost one of the step layer groups, the second insulation patterns 275 at upper two levels, respectively, and an upper portion of the second insulation pattern 275 at a third level from above. In some implementations, the first division pattern 480 may extend in the second direction D2 on the first region I of the first substrate 100, and a plurality of first division patterns 480 may be spaced apart from each other in the third direction D3.

In some implementations, some of the first division patterns 480 may extend through and contact an end portion in the second direction D2 of the third insulation pattern 350. As the first division pattern 480 is formed, the upper two step layers of the gate electrode structure, that is, each of the first and second gate electrodes 561 and 562 in the uppermost one of the step layer groups may be divided in the third direction D3 by the third insulation pattern 350 and the first division pattern 480.

The sixth to eighth insulating interlayers 590, 610 and 640 may be sequentially stacked on the fifth insulating interlayer 490 and the memory channel structure 470.

The second contact plug 600 may extend in the first direction D1 through the third to sixth insulating interlayers 330, 390, 490 and 590, a portion of the gate electrode structure, the second insulation patterns 275 and an upper portion of the first insulation pattern 700 on the second region II of the first substrate 100, and a plurality of second contact plugs 600 may be spaced apart from each other in the second and third directions D2 and D3.

In some implementations, some of the second contact plugs 600 may extend through the first gate electrode 561 in the uppermost one of the step layer groups and the second insulation patterns 275 and the fourth insulation patterns 353 thereunder, or may extend through the second gate electrode 562 in the uppermost one of the step layer groups and the second insulation patterns 275 and the fourth insulation patterns 353 thereunder, on the second region II of the first substrate 100.

In some implementations, some of the second contact plugs 600 may extend through the first step of the first step layer in each of the step layer groups except for the uppermost one of the step layer groups, that is, a pad of the first gate electrode 561 and a sidewall of the fifth insulation pattern 355 at the same level as the first gate electrode 561 and the second insulation patterns 275 and the fourth insulation patterns 353 thereunder, or may extend through the second step of the second step layer in each of the step layer groups except for the uppermost one of the step layer groups, that is, a pad of the second gate electrode 562 and a sidewall of the sixth insulation pattern 356 at the same level as the second gate electrode 562 and the second insulation patterns 275 and the fourth insulation patterns 353 thereunder, on the second region II of the first substrate 100.

Accordingly, sidewalls of the some of the second contact plugs 600 may not be entirely surrounded (unbounded) but partially surrounded by the first gate electrode 561 or the second gate electrode 562, and other portions of the sidewalls of the some of the second contact plugs 600 may be surrounded by the fifth insulation pattern 355 or the sixth insulation pattern 356.

In some implementations, the support structures 380 may be located at respective vertices of a polygon, e.g., a rectangle surrounding the second contact plug 600 in a plan view.

The second via 620 may extend through the seventh insulating interlayer 610 to contact an upper surface of the second contact plug 600, and the third via 630 may extend through the fifth to seventh insulating interlayers 490, 590 and 610 to contact an upper surface of the capping pattern 460.

The third and fourth wirings 650 and 660 may extend through the eighth insulating interlayer 640, and may contact upper surfaces of the second and third vias 620 and 630, respectively. In some implementations, the fourth wiring 660 may extend in the third direction D3 on the first region I of the first substrate 100, and a plurality of fourth wirings 660 may be spaced apart from each other in the second direction D2. The fourth wiring 660 may serve as a bit line of the semiconductor device.

In some implementations, the second contact plug 600 may extend through the gate electrode structure on the second region II of the first substrate 100, however, may contact only one of the first and second gate electrodes 561 and 562 included in the gate electrode structure to be electrically connected thereto.

In some implementations, the second contact plug 600 may extend through the first step of the first step layer included in the gate electrode structure, that is, the pad of the first gate electrode 561 and the fifth insulation pattern 355 adjacent thereto to be electrically connected to the first gate electrode 561, or may extend through the second step of the second step layer included in the gate electrode structure, that is, the pad of the second gate electrode 562 and the sixth insulation pattern 356 adjacent thereto to be electrically connected to the second gate electrode 562.

The fourth insulation patterns 353 may be disposed adjacent to the first and second gate electrodes 561 and 562, respectively, under the first gate electrode 561 or the second gate electrode 562 through which the second contact plug 600 extends, and the second contact plug 600 may extend through and contact the fourth insulation patterns 353 instead of the first and second gate electrodes 561 and 562 so as to be electrically insulated from the first and second gate electrodes 561 and 562.

Each of the fourth insulation patterns 353 may have a sufficient area, and thus the second contact plug 600 may not be electrically connected to undesired first and second gate electrodes 561 and 562, so that the semiconductor device may have enhanced electrical characteristics.

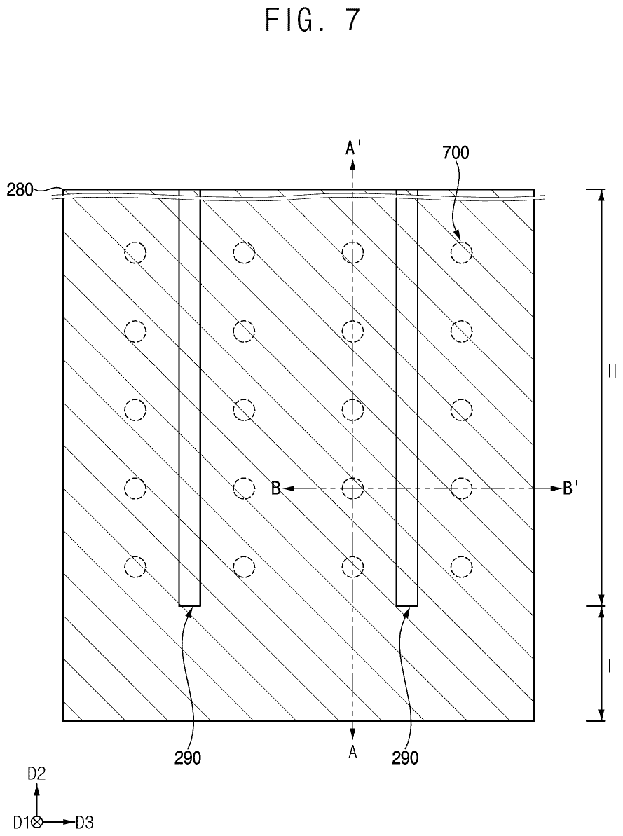

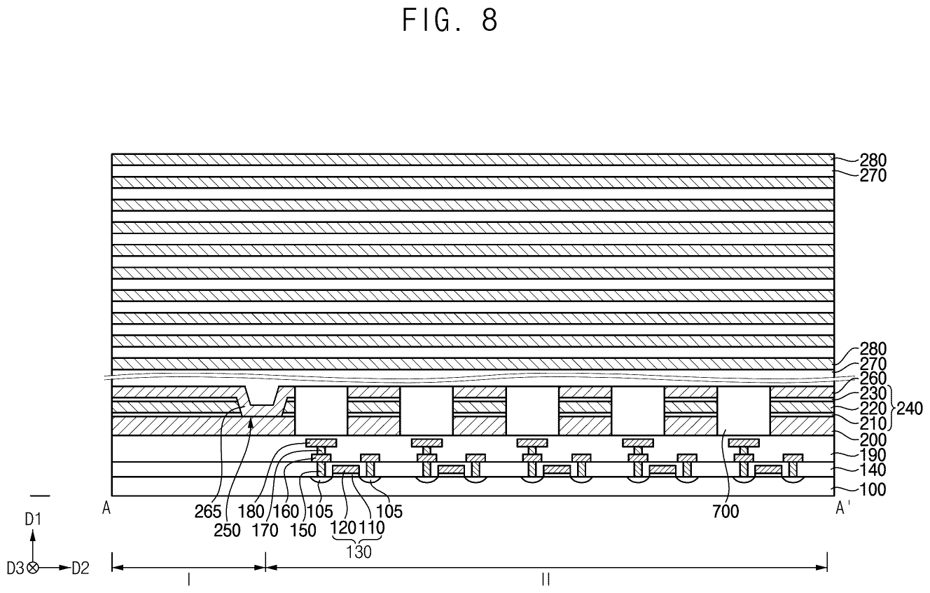

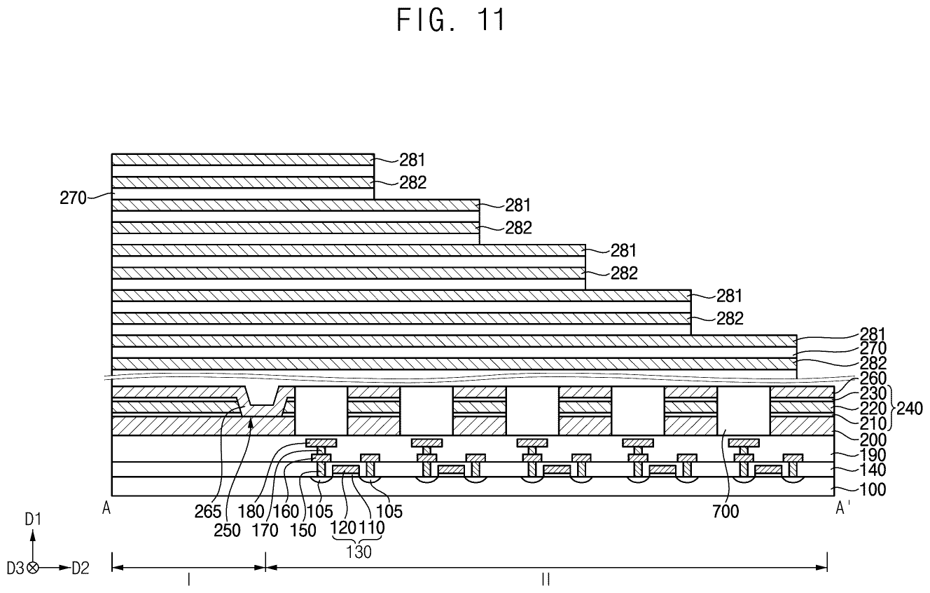

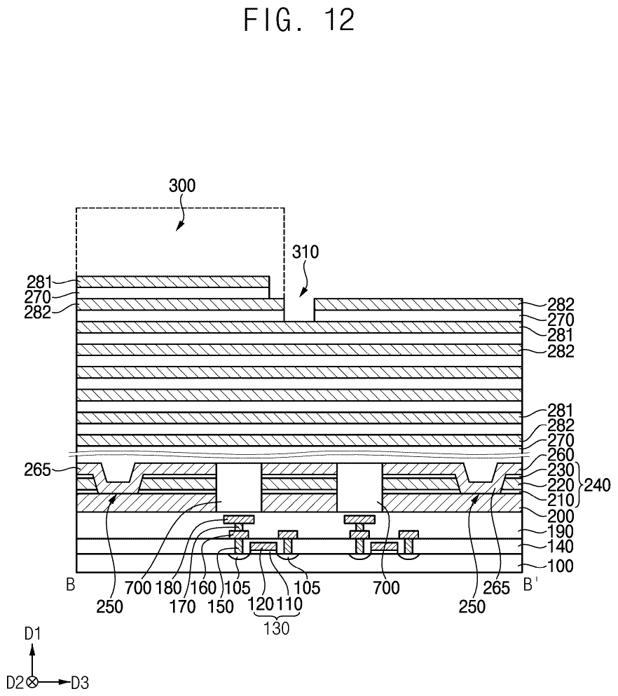

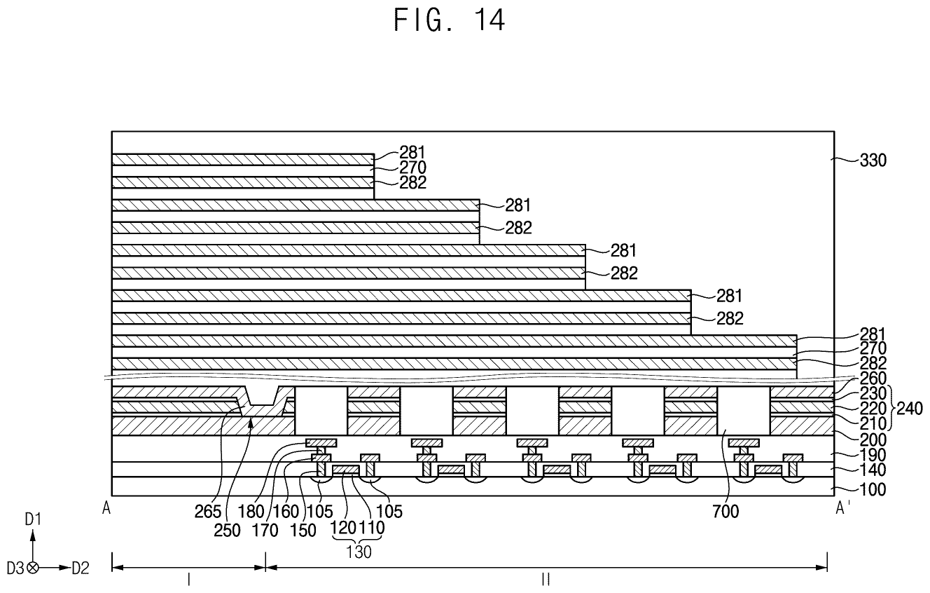

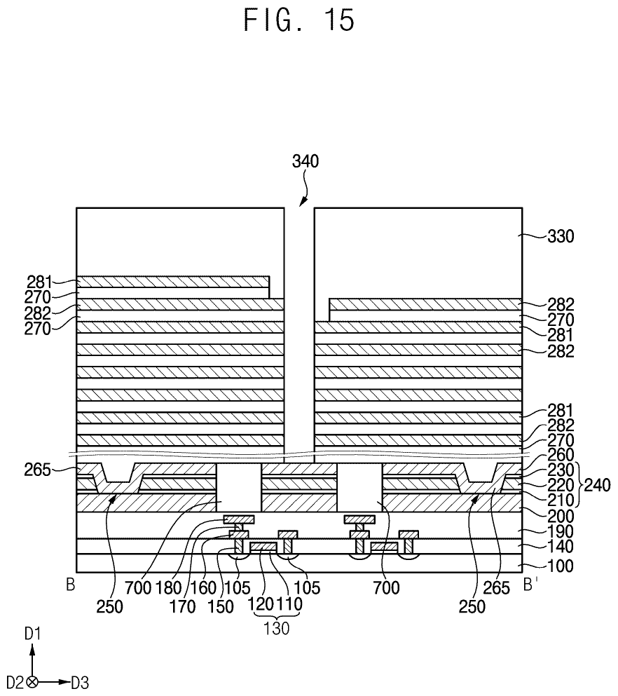

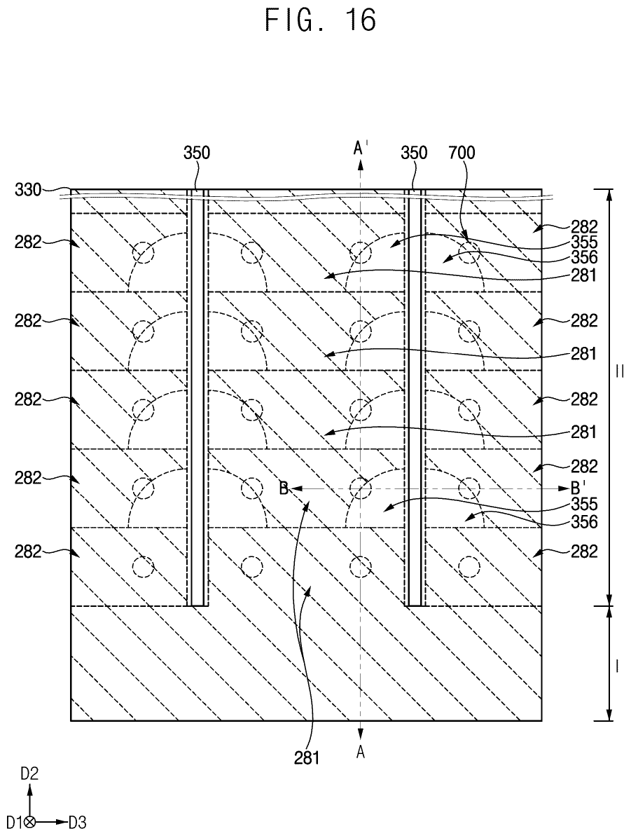

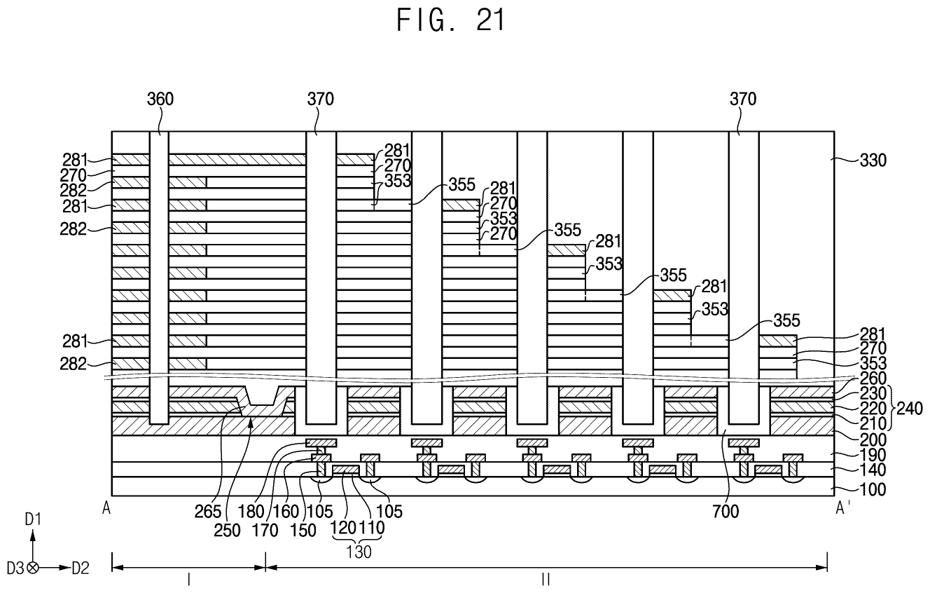

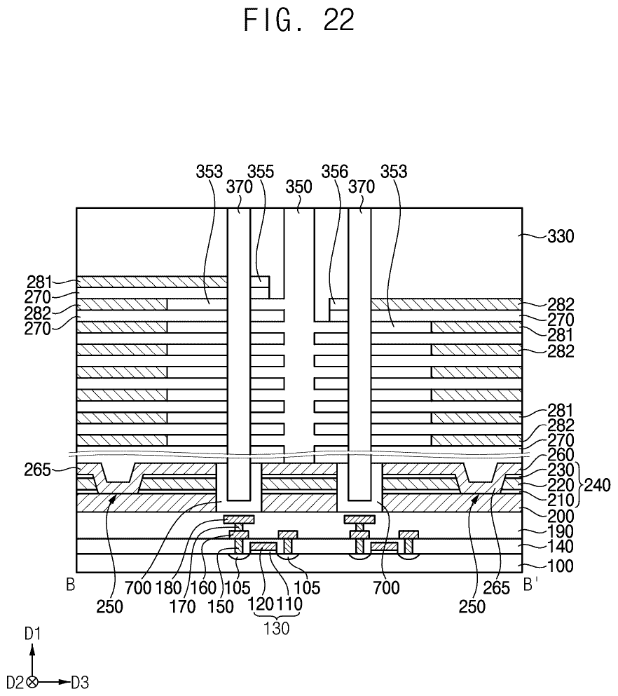

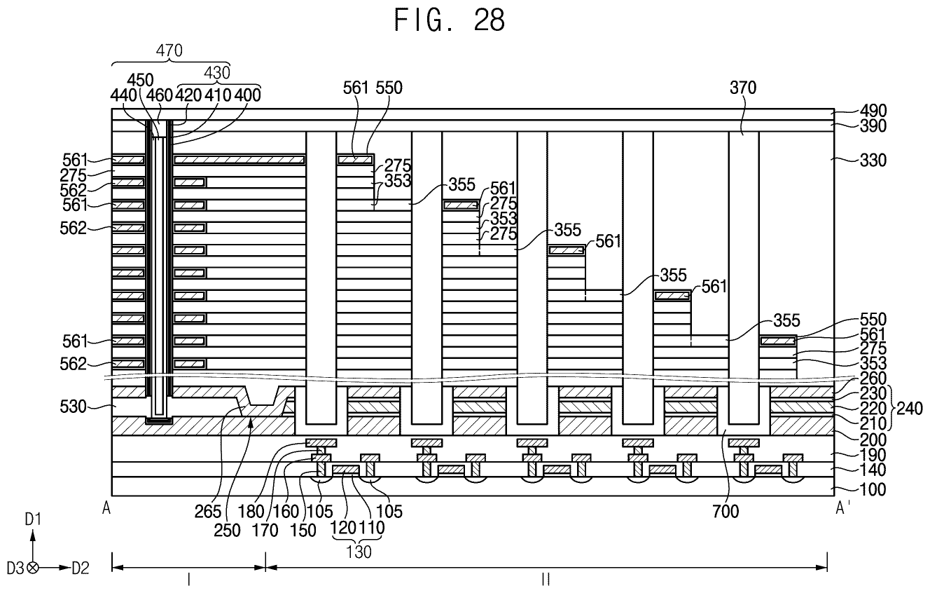

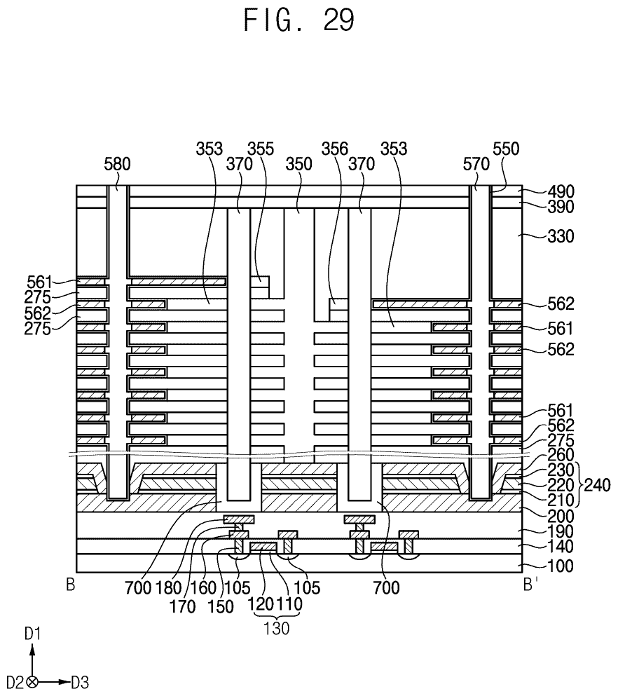

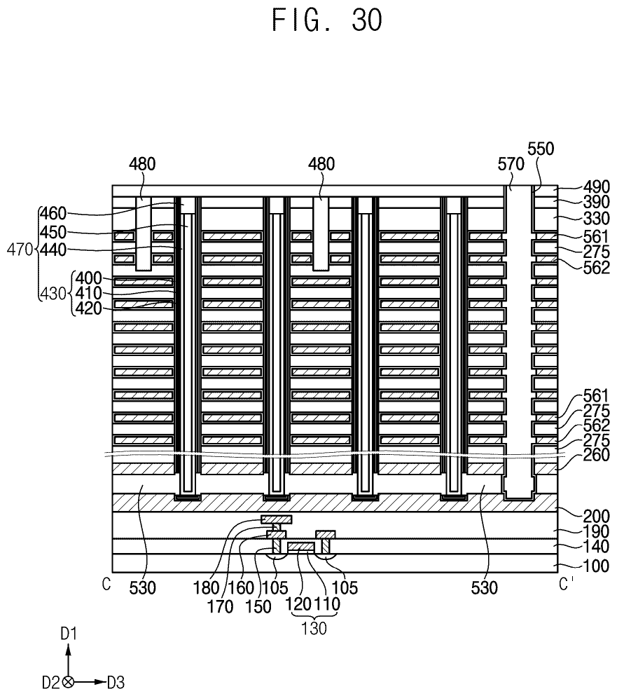

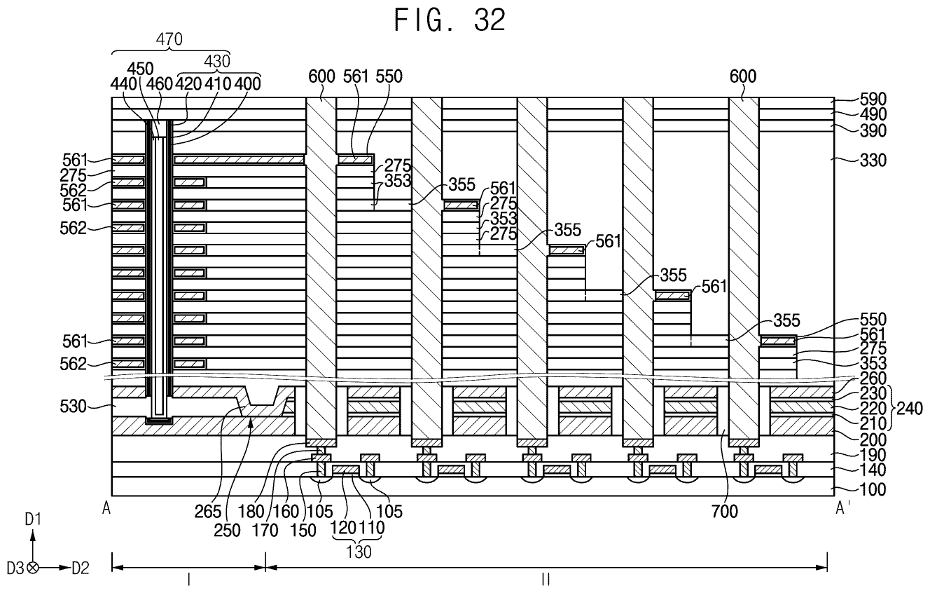

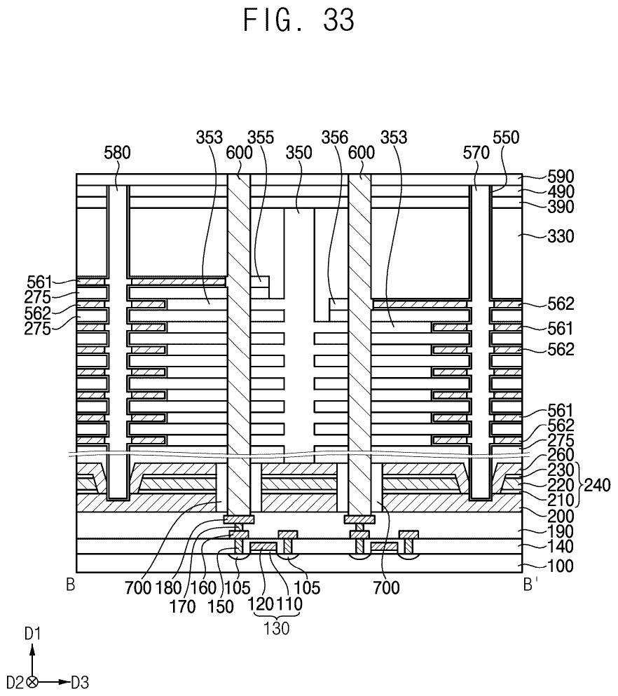

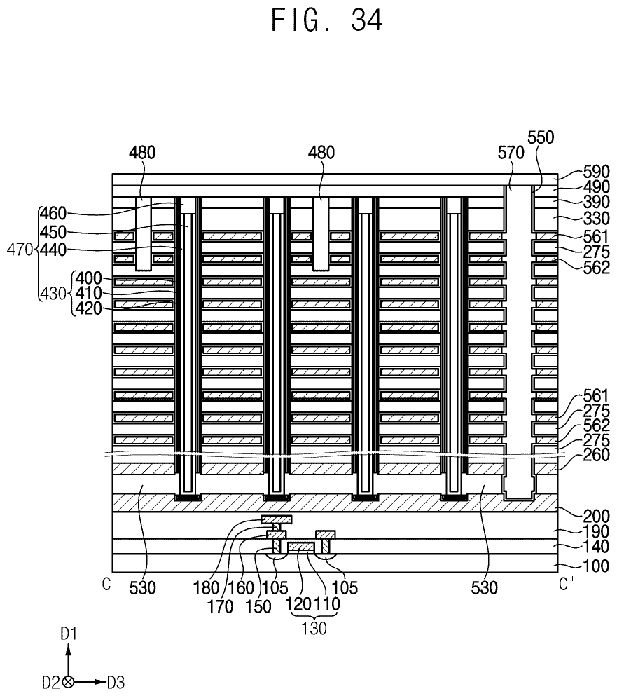

FIGS. 7 to 34 are plan views and cross-sectional views illustrating an example of a method of manufacturing a semiconductor device according to some implementations. For example, FIGS. 7, 10, 13, 16, 20, 23, 25, 27 and 31 are plan views, and FIGS. 8-9, 11-12, 14-15, 17-19, 21-22, 24, 26, 28-30 are cross-sectional views.

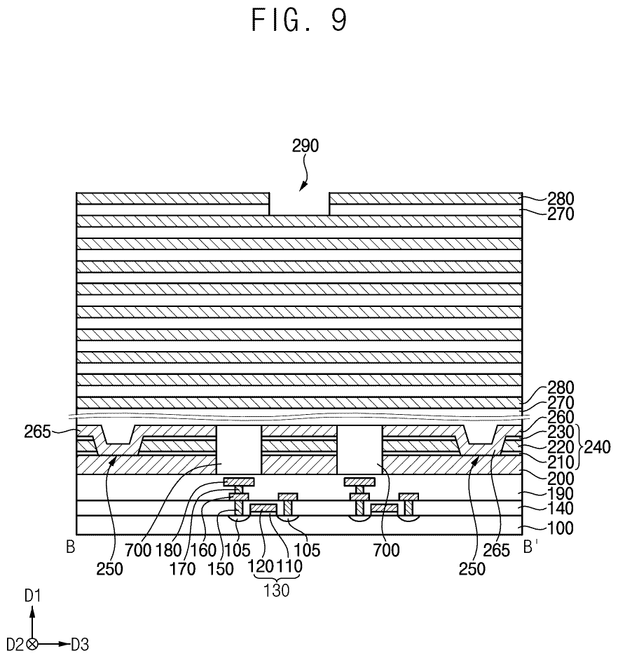

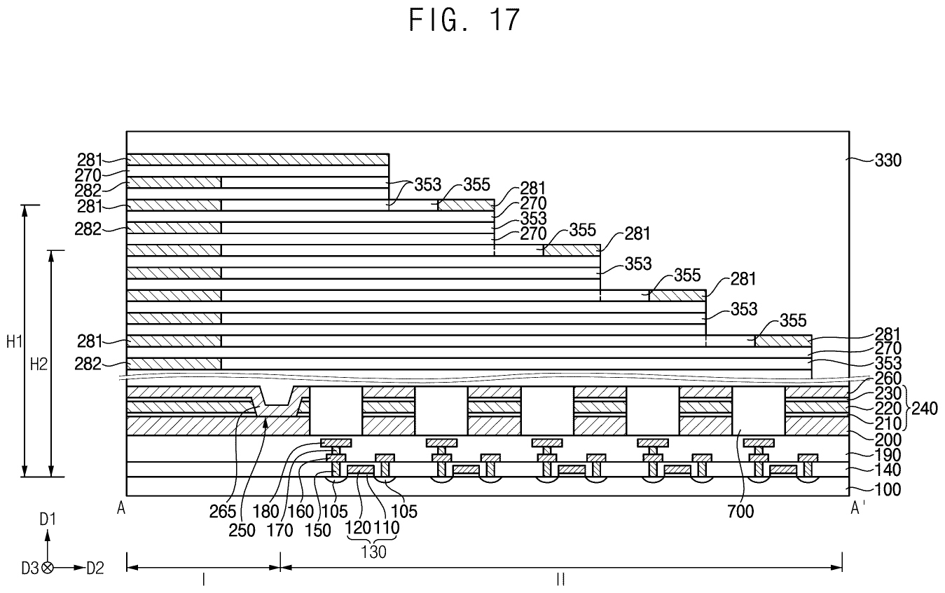

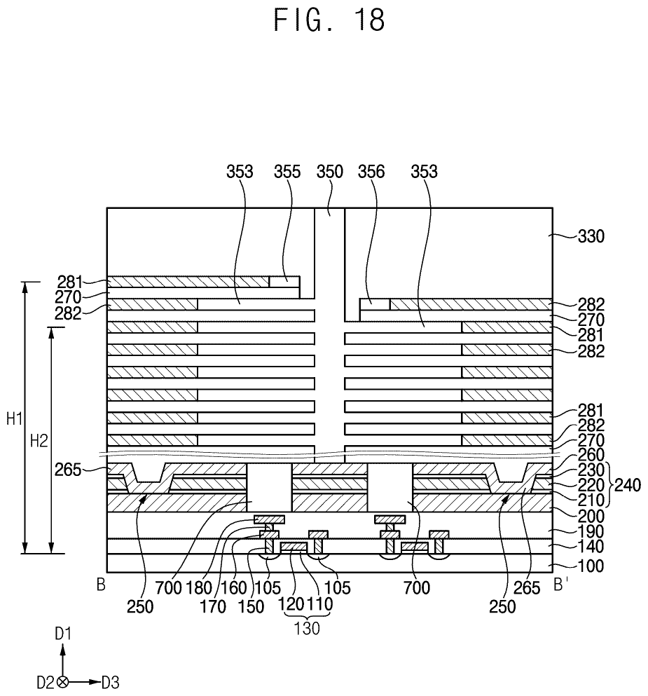

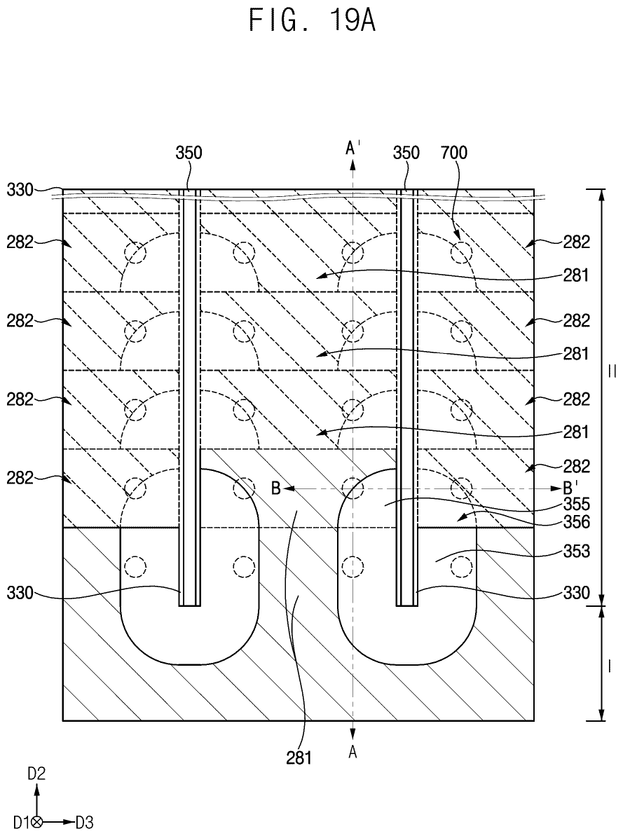

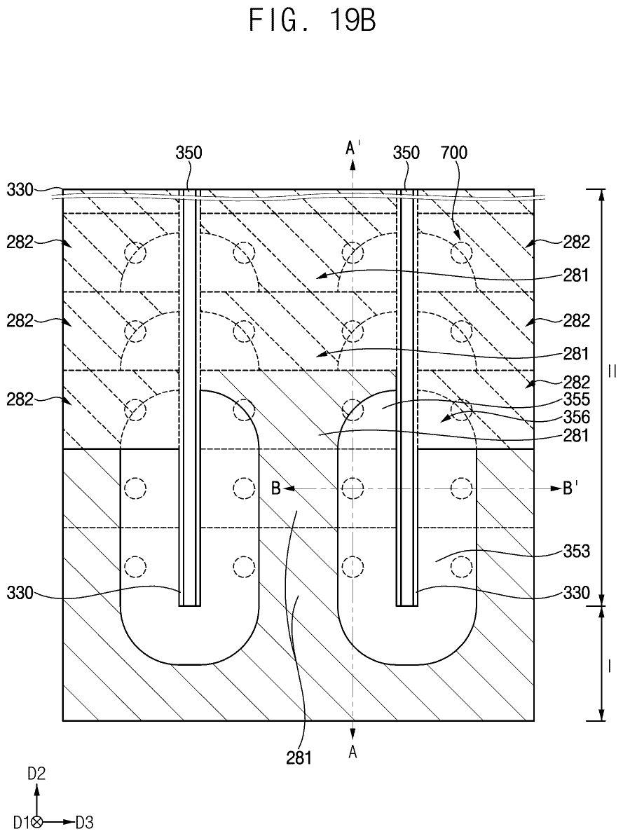

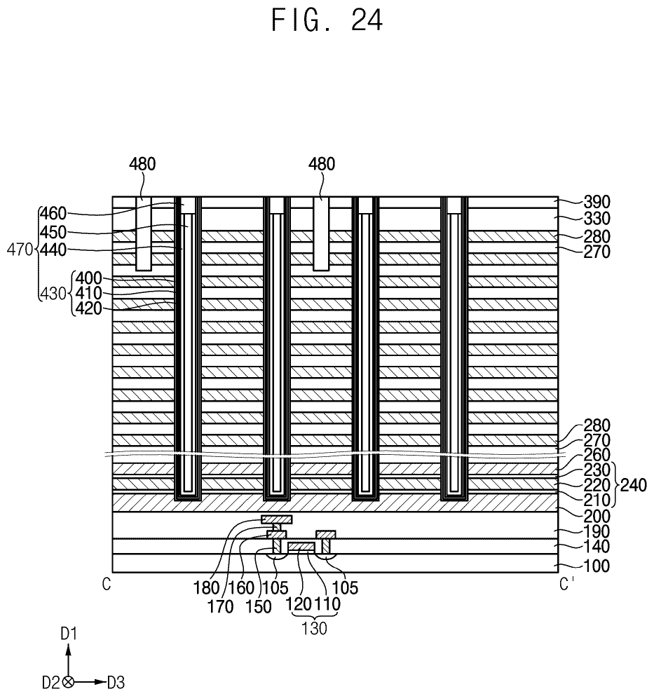

FIGS. 8, 11, 14, 17, 21, 28 and 32 are vertical cross-sectional views taken along lines A-A′ of corresponding plan views, respectively, each of FIGS. 9, 12, 15, 18, 22, 29 and 33 are vertical cross-sectional views taken along lines B-B′ of corresponding plan views, respectively, and FIGS. 24, 26, 30 and 34 are cross-sectional views taken along lines C-C′ of corresponding plan views, respectively. FIG. 19A is a horizontal cross-sectional view at a height H1 of FIGS. 17 and 18, and FIG. 19B is a horizontal cross-sectional view at a height H2 of FIGS. 17 and 18. FIGS. 7 to 34 show region X of FIG. 1.

In FIGS. 7 to 9, a lower circuit pattern may be formed on a first substrate 100, and first and second insulating interlayers 140 and 190 may be sequentially stacked on the first substrate 100 to cover the lower circuit pattern.

Each element of the lower circuit pattern may be formed by a patterning process or a damascene process.

A CSP 200 and a sacrificial layer structure 240 may be sequentially formed on the second insulating interlayer 190, the sacrificial layer structure 240 may be partially removed to form a first opening 250 exposing an upper surface of the CSP 200, and a support layer 260 may be formed on an upper surface of the sacrificial layer structure 240 and the exposed upper surface of the CSP 200.

The sacrificial layer structure 240 may include first, second and third sacrificial layers 210, 220 and 230 sequentially stacked. Each of the first and third sacrificial layers 210 and 230 may include an oxide, e.g., silicon oxide, and the second sacrificial layer 220 may include a nitride, e.g., silicon nitride.

The first openings 250 may be formed with various layouts in a plan view. For example, a plurality of first openings 250 may be spaced apart from each other in each of the second and third directions D2 and D3 on the first region I of the first substrate 100, the first opening 250 may extend in the third direction D3 on a boundary between the first and second regions I and II of the first substrate 100, and a plurality of first openings 250, each of which may extend in the second direction D2, may be spaced apart from each other in the third direction D3 on the second region II of the first substrate 100.

FIG. 8 shows the first openings 250 extending in the third direction D3 on the boundary between the first and second regions I and II of the first substrate 100, and FIG. 9 shows the plurality of first openings 250, each of which extends in the second direction D2, spaced apart from each other in the third direction D3 on the second region II of the first substrate 100.

The support layer 260 may include a material having an etching selectivity with respect to the first to third sacrificial layers 210, 220 and 230, e.g., polysilicon doped with n-type impurities. The support layer 260 may be conformally formed, and thus a first recess may be formed on a portion of the support layer 260 in the first opening 250. Hereinafter, the portion of the support layer 260 in the first opening 250 which may contact the upper surface of the CSP 200 may be referred to as a support pattern 265.

A first insulation pattern 700 may be formed through the support layer 260, the sacrificial layer structure 240 and the CSP 200. In some implementations, a plurality of first insulation patterns 700 may be spaced apart from each other in the second and third directions D2 and D3 on the second region II of the first substrate 100.

A second insulation layer 270 and a fourth sacrificial layer 280 may be alternately and repeatedly stacked in the first direction D1 on the support layer 260, the support pattern 265 and the first insulation pattern 700, and a mold layer including the second insulation layers 270 and the fourth sacrificial layers 280 may be formed. The second insulation layer 270 may include an oxide, e.g., silicon oxide, and the fourth sacrificial layer 280 may include a material having an etching selectivity with respect to the second insulation layer 270, e.g., a nitride, such as silicon nitride.

An uppermost one of the fourth sacrificial layers 280 and an uppermost one of the second insulation layers 270 may be partially removed to form a second opening 290 extending in the second direction D2 on the second region II of the first substrate 100 to expose an upper surface of one of the fourth sacrificial layers 280 at a second level from above. In some implementations, a plurality of second openings 290 may be spaced apart from each other in the third direction D3.

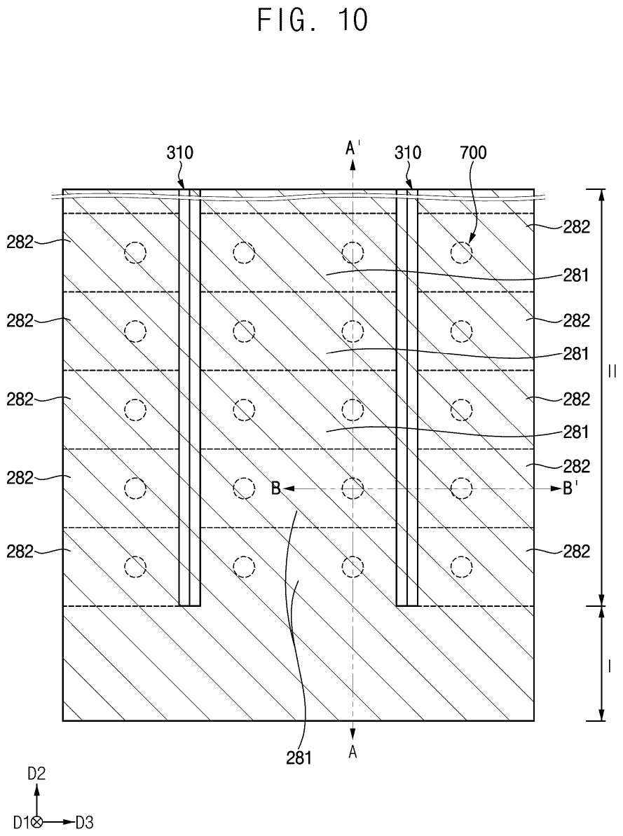

In FIGS. 10 to 12, a first photoresist pattern 300 may be formed on the uppermost one of the fourth sacrificial layers 280, the uppermost one of the second insulation layers 270 and the one of the fourth sacrificial layers 280 at the second level from above, and the mold layer may be etched using the first photoresist pattern 300 as an etching mask.

In some implementations, the first photoresist pattern 300 may partially cover the upper surface of the fourth sacrificial layer 280 exposed by the second opening 290.

A trimming process in which a planar area of the first photoresist pattern 300 is reduced by a given ratio may be performed, and an etching process may be performed on the mold layer using the reduced first photoresist pattern 300 as an etching mask. The etching process and the trimming process may be repeatedly performed to form a preliminary staircase structure including a plurality of step layers each of which may include the second insulation layer 270 and the fourth sacrificial layer 280 sequentially stacked at an upper portion of the mold layer.

After removing the first photoresist pattern 300, a second photoresist pattern may be formed to partially cover the preliminary staircase structure, and an etching process may be performed on the mold layer including the preliminary staircase structure using the second photoresist pattern as an etching mask. Additionally, a trimming process on the second photoresist pattern and the etching process on the mold layer may be repeatedly performed to form a mold having a staircase structure including a plurality of step layers each of which may include the second insulation layer 270 and the fourth sacrificial layer 280 sequentially stacked.

In some implementations, the staircase structure may include a plurality of step layer groups, each of which may include a plurality of step layers stacked in the first direction D1, stacked in the first direction D1. Lengths in the second direction D2 of the step layer groups, respectively, may increase from a lowermost level toward an uppermost level.

In some implementations, end portions in the second direction D2 of the step layers included in each of the step layer groups may form steps, which may be disposed in the third direction D3.

In some implementations, each of the step layer groups may include an even number of step layers, e.g., two step layers, four step layers, six step layers, etc., and thus each of the step layer groups may include an even number of steps, e.g., two steps, four steps, six steps, etc., disposed in the third direction D3 on the second region II of the first substrate 100. FIGS. 10 to 12 show that each of the step layer groups includes two step layers.

Hereinafter, first ones of the step layers in each of the step layer groups that may be disposed at odd-numbered levels from a top may be referred to as a first step layer, while second ones of the step layers in each of the step layer groups that may be disposed at even-numbered levels from a top may be referred to as a second step layer. Additionally, a first one of the fourth sacrificial layers 280 included in the first step layer may be referred to as a fifth sacrificial layer 281, and a second one of the fourth sacrificial layers 280 included in the second step layer may be referred to as a sixth sacrificial layer 282. Accordingly, if each of the step layer groups includes two step layers, an upper step layer may be the first step layer, and a lower step layer may be the second step layer. The first and second step layers include first and second steps, respectively, which may be disposed in the third direction D3.

A third opening 310 may be formed to extend in the second direction D2 through the second step of the second step layer included in each of the step layer groups at a position adjacent to a sidewall in the third direction D3 of the first step of the first step layer, and may expose an upper surface of the fifth sacrificial layer 281 included in a step layer group disposed directly under each of the step layer groups. In some implementations, the third opening 310 may overlap the second opening 290 in the first direction D1, and a width in the third direction D3 of the third opening 310 may be smaller than a width in the third direction D3 of the second opening 290.

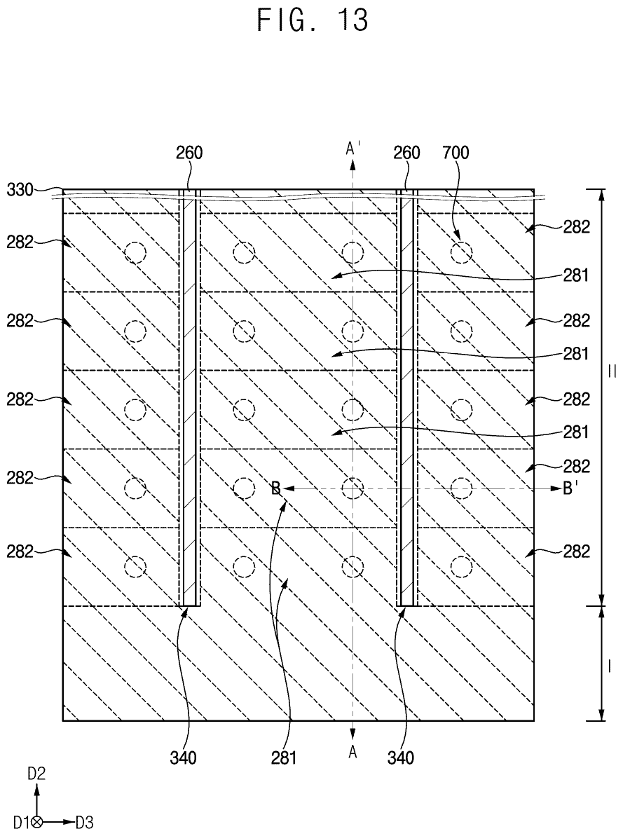

In FIGS. 13 to 15, a third insulating interlayer 330 may be formed on the CSP 200 to cover the mold, and a fourth opening 340 may be formed through the third insulating interlayer 330 and the mold to expose an upper surface of the support layer 260.

In some implementations, the fourth opening 340 may partially overlap the third opening 310 in the second step of the second step layer included in each of the step layer groups. For example, the fourth opening 340 may extend through a sidewall of the second step of the second step layer included in each of the step layer groups that may be adjacent to the third opening 310, and may be spaced apart from another sidewall of the second step of the second step layer adjacent to the third opening 310. The fourth opening 340 may be spaced apart from a sidewall in the third direction D3 of the first step of the first step layer included in each of the step layer group in the third direction D3.

The fourth opening 340 may extend in the first direction D1 through other ones of the step layer groups under each of the step layer groups.

In FIGS. 16 to 19, the fifth and sixth sacrificial layers 281 and 282 of which sidewalls are exposed by the fourth opening 340 may be partially removed to form second to fourth recesses, and third to sixth insulation patterns 350, 353, 355 and 356 may be formed to fill the fourth opening 340 and the second to fourth recesses, respectively.

The third insulation pattern 350 may be formed in the fourth opening 340, and may extend through the third insulating interlayer 330 and the mold in the second direction D2 on the second region II of the first substrate 100.

In some implementations, the second recess may be formed by removing a portion of the sixth sacrificial layer 282 within a given distance from a sidewall in the third direction D3 of the second step of the second step layer included in each of the step layer groups that may be exposed by the fourth opening 340. Additionally, the second recess may be formed by removing portions of the fifth and sixth sacrificial layers 281 and 282 within a given distance from each of opposite sidewalls in the third direction D3 exposed by the fourth opening 340 of the first and second step layers included in other ones of the step layer groups under each of the step layer groups. Accordingly, a plurality of second recesses may be formed to be spaced apart from each other in the first direction D1.

In some implementations, each of the second recess may have a semi-circular shape or a U shape of which a center is located at an end portion of the fourth opening 340 in the second direction D2, on the first region I of the first substrate 100 in a plan view. End portions in the second direction D2 of the second recesses disposed in the first direction D1 on the first region I of the first substrate 100 may be aligned with each other in the first direction D1.

In some implementations, the fourth insulation pattern 353 in the second recess may extend in the third direction D3 to a given length from a sidewall of the third insulation pattern 350 in the third direction D3, and a plurality of fourth insulation patterns 353 may be formed in the first direction D1. Lengths in the second direction D2 of the fourth insulation patterns 353 may increase from an uppermost level toward a lowermost level, and lengths in the third direction D3 of the fourth insulation patterns 353, except for opposite end portions thereof, may be substantially constant. Additionally, an end portion in the second direction D2 of each of the fourth insulation patterns 353 may be formed on the first region I of the first substrate 100, and may have a semi-circular shape or a U shape in a plan view.

The fourth opening 340 may be spaced apart from a sidewall in the third direction D3 of the first step of the first step layer in each of the step layer groups, and thus the fifth sacrificial layer 281 may not be removed from a portion of the fourth opening 340 extending through each of the step layer groups. Additionally, the fourth opening 340 may be spaced apart from a sidewall in the third direction D3 of the second step of the second step layer in each of the step layer groups, and thus the sixth sacrificial layer 282 may not be removed from the portion of the fourth opening 340 extending through each of the step layer groups.

However, in some implementations, the fourth opening 340 may entirely extend through the mold, and in each of the step layer groups, the fifth and sixth sacrificial layers 281 and 282 may be partially removed from a portion of the fourth opening 340 overlapping in the first direction D1 a portion of the fourth opening 340 extending through one of the step layer groups over each of the step layer groups and being at substantially the same height as each of the step layer groups to form the third and fourth recesses, respectively.

Accordingly, a portion of the fifth sacrificial layer 281 included in the first step of the first step layer in each of the step layer groups may be removed by a shape of a quadrant to form the third recess in a plan view, and a portion of the sixth sacrificial layer 282 included in the second step of the second step layer in each of the step layer groups may be removed by a shape of a quadrant to form the fourth recess in a plan view.

In some implementations, the fifth and sixth insulation patterns 355 and 356 in the third and fourth recesses, respectively, may have a shape of a quadrant in a plan view, and may contact sidewalls of the fifth and sixth sacrificial layers 281 and 282, respectively. The fifth and sixth insulation patterns 355 and 356 may be symmetrical with respect to the third insulation pattern 350 in a plan view.

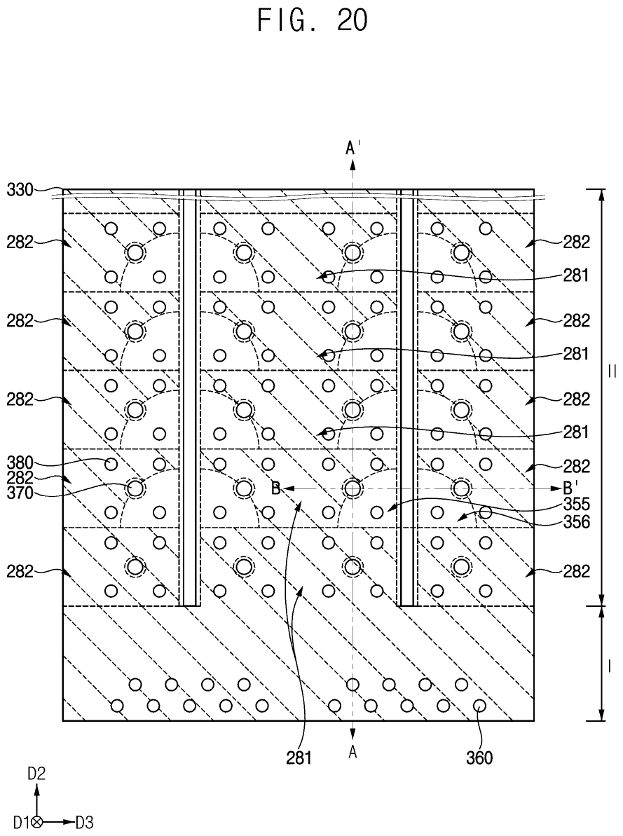

In FIGS. 20 to 22, an etching process may be performed to form a first hole extending in the first direction D1 through the third insulating interlayer 330, the mold, the support layer 260 and the sacrificial layer structure 240 to expose an upper surface of the CSP 200 on the first region I of the first substrate 100, a second hole extending in the first direction D1 through the third insulating interlayer 330, a portion of the mold and an upper portion of the first insulation pattern 700 on the second region II of the first substrate 100, and a third hole extending in the first direction D1 through the third insulating interlayer 330, a portion of the mold, the support layer 260 and the sacrificial layer structure 240 to expose an upper surface of the CSP 200 on the second region II of the first substrate 100.

In some implementations, a plurality of first holes may be spaced apart from each other in each of the second and third directions D2 and D3 on the first region I of the first substrate 100, a plurality of second holes may be spaced apart from each other in each of the second and third directions D2 and D3 on the second region II of the first substrate 100, and a plurality of third holes may be spaced apart from each other in each of the second and third directions D2 and D3 on the second region II of the first substrate 100. The first to third holes may be formed by the same etching process, or may be sequentially formed by respective etching processes.

In some implementations, each of the first to third holes may have a shape of, e.g., a circle, an ellipse, a polygon, or a polygon with rounded corners.

Seventh to ninth sacrificial patterns 360, 370 and 380 may be formed in the first to third holes, respectively. The seventh to ninth sacrificial patterns 360, 370 and 380 may be formed by forming a seventh sacrificial layer on the CSP 200, the first insulation pattern 700 and the third insulating interlayer 330 to fill the first to third holes, and planarizing the seventh sacrificial layer until an upper surface of the third insulating interlayer 330 is exposed. The seventh sacrificial layer may include, e.g., polysilicon.

In some implementations, a plurality of seventh sacrificial patterns 360 may be formed to be spaced apart from each other in each of the second and third directions D2 and D3 on the first region I of the first substrate 100.

In some implementations, the eighth sacrificial pattern 370 may extend through the fifth sacrificial layer 281 of the first step layer in an uppermost one of the step layer group and the second insulation layers 270 and the fourth insulation patterns 353 thereunder, or may extend through the sixth sacrificial layer 282 of the second step layer in the uppermost one of the step layer group and the second insulation layers 270 and the fourth insulation patterns 353 thereunder, on the second region II of the first substrate 100.

In some implementations, the eighth sacrificial pattern 370 may extend through the fifth sacrificial layer 281 of the first step of the first step layer in each of other step layer groups except for the uppermost one of the step layer groups and a sidewall of the fifth insulation pattern 355 to extend through the second insulation layers 270 and the fourth insulation patterns 353 thereunder, or may extend through the sixth sacrificial layer 282 of the second step of the second step layer in each of the other step layer groups except for the uppermost one of the step layer groups and a sidewall of the sixth insulation pattern 356 to extend through the second insulation layers 270 and the fourth insulation patterns 353 thereunder.

Accordingly, a plurality of eighth sacrificial patterns 370 may be formed to be spaced apart from each other in each of the second and third directions D2 and D3 on the second region II of the first substrate 100.

In some implementations, the ninth sacrificial patterns 380 may be formed at respective vertices of a polygon, e.g., a rectangle surrounding the eighth sacrificial pattern 370 in a plan view.

Accordingly, first ones of the ninth sacrificial patterns 380 may extend through the fifth sacrificial layer 281 of the first step of the first step layer in the uppermost one of the step layer groups and the second insulation layers 270 and the fourth insulation patterns 353 thereunder, or may extend through the sixth sacrificial layer 282 of the second step of the second step layer in the uppermost one of the step layer groups and the second insulation layers 270 and the fourth insulation patterns 353 thereunder.

Additionally, second ones of the ninth sacrificial patterns 380 may extend through the fifth sacrificial layer 281 of the first step of the first step layer in each of the other step layer groups except for the uppermost one of the step layer groups or the sixth sacrificial layer 282 of the second step of the second step layer in each of the other step layer groups except for the uppermost one of the step layer groups to extend through the second insulation layers 270 and the fourth insulation patterns 353.

Furthermore, third ones of the ninth sacrificial patterns 380 may extend through the fifth sacrificial layer 281 of the first step of the first step layer or the sixth sacrificial layer 282 of the second step of the second step layer in the other ones of the step layer groups except for the uppermost one of the step layer groups to extend through the second insulation layers 270 and the fourth insulation patterns 353 thereunder. Fourth ones of the ninth sacrificial patterns 380 may extend through the fifth insulation pattern 355 or the sixth insulation pattern 356 contacting the fifth sacrificial layer 281 of the first step of the first step layer or the sixth sacrificial layer 282 of the second step of the second step layer in each of the step layer groups to extend through the second insulation layers 270 and the fourth insulation patterns 353 thereunder.

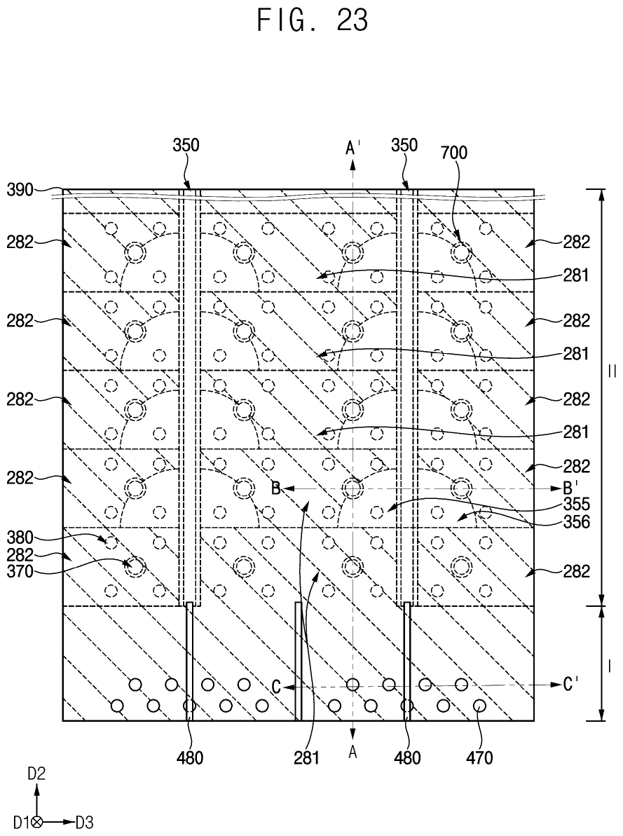

In FIGS. 23 and 24, a fourth insulating interlayer 390 may be formed on the third insulating interlayer 330 and the seventh to ninth sacrificial patterns 360, 370 and 380, and the fourth insulating interlayer 390 may be patterned to expose the seventh sacrificial pattern 360, and the exposed seventh sacrificial pattern 360 may be removed to form the first hole exposing an upper surface of the CSP 200 again.

A charge storage structure layer and a channel layer may be sequentially formed on a sidewall of the first hole, the exposed upper surface of the CSP 200 and an upper surface of the fourth insulating interlayer 390, and a filling layer may be formed on the channel layer to fill a remaining portion of the first hole. The charge storage structure layer may include a first blocking layer, a charge storage layer, and a tunnel insulation layer sequentially stacked.

The filling layer, the first channel layer, and the charge storage structure layer may be planarized until the upper surface of the fourth insulating interlayer 390 is exposed. Accordingly, a charge storage structure 430, a channel 440 and a filling pattern 450 may be formed in the first hole. The charge storage structure 430 may include a first blocking pattern 400, a charge storage pattern 410 and a tunnel insulation pattern 420 sequentially stacked.

Upper portions of the filling pattern 450 and the channel 440 may be removed to form a fifth recess, and a capping pattern 460 may be formed to fill the fifth recess.

The charge storage structure 430, the channel 440, the filling pattern 450, and the capping pattern 460 in the first hole may collectively form a memory channel structure 470.

In some implementations, the memory channel structure 470 may have a pillar shape extending in the first direction D1. In some implementations, a plurality of memory channel structures 470 may be spaced apart from each other in each of the second and third directions D2 and D3 on the first region I of the first substrate 100.

In some implementations, when the first hole is formed, the ninth sacrificial pattern 380 may also be removed to form the second hole again, and a support structure 380 having substantially the same structure as the memory channel structure 470 may be formed in the second hole. However, the support structure 380 may not be electrically connected to other wiring structures for transferring electrical signals, and thus may also be referred to as a dummy memory channel structure. In some implementations, when the first hole is formed, the ninth sacrificial pattern 380 may not be removed but remain, and the support structure 380 may have a single layer structure including, e.g., polysilicon.

The third and fourth insulating interlayers 330 and 390, some of the fifth and sixth sacrificial layers 281 and 282, and some of the second insulation layers 270 may be etched to form a fifth opening extending therethrough in the second direction D2, and a first division pattern 480 may be formed in the fifth opening.

In some implementations, the first division pattern 480 may extend through upper portions of some of the memory channel structures 470. Additionally, the first division pattern 480 may also extend through the third and fourth insulating interlayers 330 and 390, the fifth and sixth sacrificial layers 281 and 282 included in the uppermost one of the step layer groups, ones of the second insulation layers 270 at upper two levels, respectively, and a portion of one of the second insulation layers 270 at a third level from above. The first division pattern 480 may extend in the second direction D2 on the first region I of the first substrate 100, and a plurality of first division patterns 480 may be spaced apart from each other in the third direction D3.

In some implementations, some of the first division patterns 480 may extend through an end portion in the second direction D2 of the third insulation pattern 350. As the first division pattern 480 is formed, ones of the step layers at upper two levels, respectively, in the mold, that is, the fifth and sixth sacrificial layers 281 and 282 included in the uppermost one of the step layer group may be divided in the third direction D3 by the third insulation pattern 350 and the first division pattern 480.

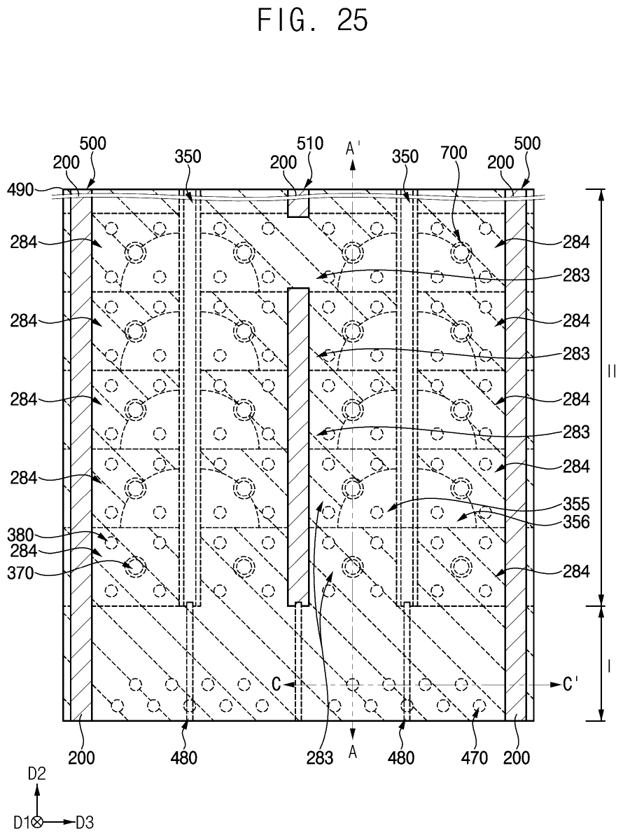

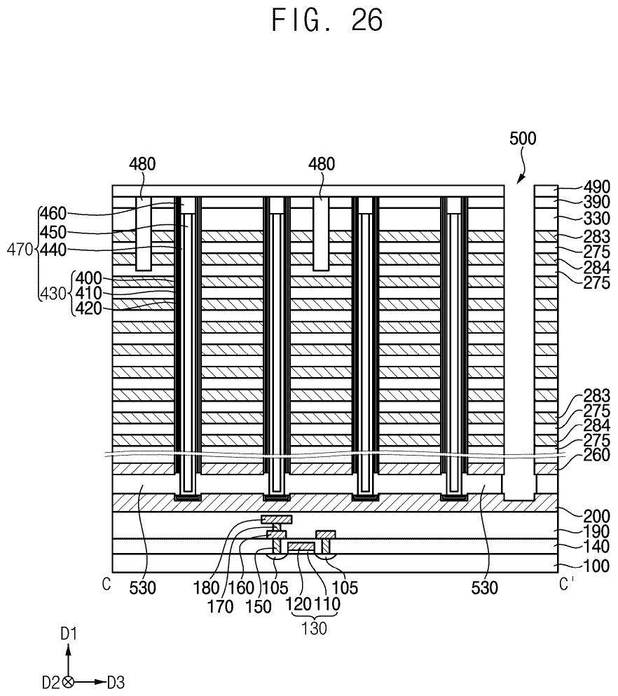

In FIGS. 25 and 26, a fifth insulating interlayer 490 may be formed on the fourth insulating interlayer 390, the memory channel structure 470, and the first division pattern 480, and sixth and seventh openings 500 and 510 may be formed through the third and fifth insulating interlayers 330, 390, and 490, the mold, the support layer 260, and the sacrificial layer structure 240 to expose an upper surface of the CSP 200.

In some implementations, the sixth opening 500 may extend in the second direction D2 on the first and second regions I and II of the first substrate 100, and a plurality of sixth openings 500 may be formed to be spaced apart from each other in the third direction D3. The sixth opening 500 may extend to opposite end portions in the second direction D2 of the mold. Accordingly, the mold may be divided into a plurality of parts in the third direction D3 by the sixth openings 500. As the sixth opening 500 is formed, the second insulation layers 270 and the fifth and sixth sacrificial layers 281 and 282 included in the mold may be divided into second insulation patterns 275 and fifth and sixth sacrificial patterns 283 and 284, each of which may extend in the second direction D2.

The seventh opening 510 may be formed to extend in the second direction D2 by a given length between neighboring ones of the third insulation patterns 350 in the third direction D3 on the second region II of the first substrate 100. In some implementations, a plurality of seventh openings 510 may be formed to be spaced apart from each other in the second direction D2 on the second region II of the first substrate 100. In some implementations, the seventh opening 510 may continuously extend in the second direction D2 on the second region II of the first substrate 100. In some implementations, an end of the seventh opening 510 adjacent to the first region I of the first substrate 100 may extend through an end portion of the first division pattern 480 in the second direction D2.

In some implementations, each of the sixth and seventh openings 500 and 510 may expose the upper surface of the CSP 200, and further extend through an upper portion of the CSP 200. In some implementations, each of the sixth and seventh openings 500 and 510 may extend through the support pattern 265 instead of the support layer 260 and the sacrificial layer structure 240 on the second region II of the first substrate 100.

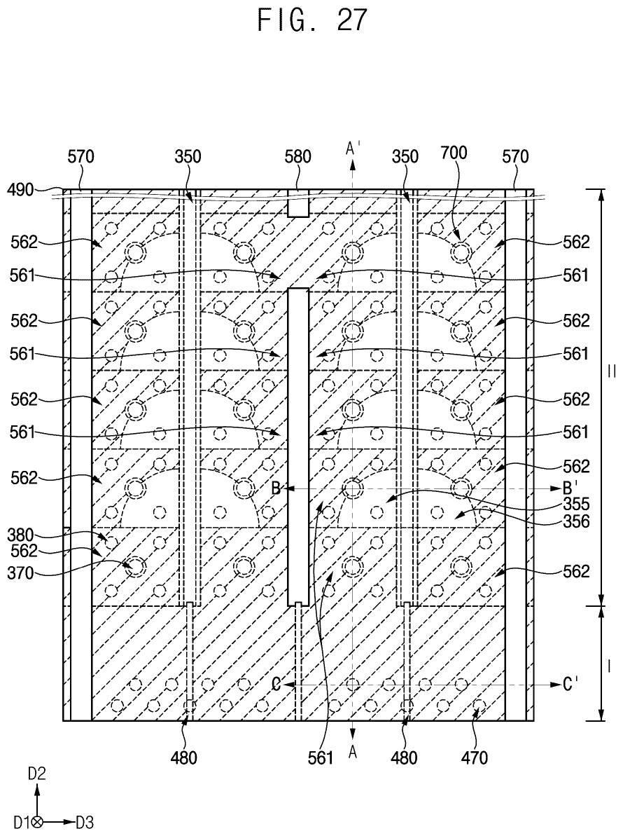

In FIGS. 27 to 30, the sacrificial layer structure 240 may be removed by an etching process through the sixth and seventh openings 500 and 510 to form a first gap, and a channel connection pattern 530 may be formed in the first gap. The channel connection pattern 530 may be formed on the first region I of the first substrate 100. In some implementations, each of the sixth and seventh openings 500 and 510 may extend through the support pattern 265 instead of the support layer 260 and the sacrificial layer structure 240 on the second region II of the first substrate 100, and the sacrificial layer structure 240 may not be removed by the etching process through the sixth and seventh openings 500 and 510, and the channel connection pattern 530 may not be formed.

The fifth and sixth sacrificial patterns 283 and 284 exposed by the sixth and seventh openings 500 and 510 may be removed to form second and third gaps between the second insulation patterns 275 at respective levels, and a portion of an outer sidewall of the charge storage structure 430 included in the memory channel structure 470 and a portion of an outer sidewall of the support structure 380 may be exposed by the second and third gaps.

In some implementations, the fifth and sixth sacrificial patterns 283 and 284 may be removed by a wet etching process using, e.g., phosphoric acid (H₃PO₄) or sulfuric acid (H₂SO₄).

A second blocking layer may be formed on sidewalls of the second insulation pattern 275 and the third to fifth insulating interlayers 330, 390 and 490 exposed by the sixth and seventh openings 500 and 510, inner walls of the second and third gaps, the outer sidewalls of the charge storage structure 430 and the support structure 380 exposed by the second and third gaps and an upper surface of the fifth insulating interlayer 490, and a gate electrode layer may be formed on the second blocking layer.

The gate electrode layer may include a gate barrier layer and a gate conductive layer sequentially stacked. The gate electrode layer may be partially removed to form first and second gate electrodes 561 and 562 in the second and third gaps, respectively. In some implementations, the gate electrode layer may be partially removed by a wet etching process.

In some implementations, each of the first and second gate electrodes 561 and 562 may extend in the second direction D2, and the first and second gate electrodes 561 and 562 may be alternately and repeatedly stacked in the first direction D1 to form a gate electrode structure. The gate electrode structure may have a staircase shape including the first and second gate electrodes 561 and 562 as respective step layers.

A plurality of gate electrode structures may be spaced apart from each other in the third direction D3 by the sixth openings 500. The seventh opening 510 may not extend to opposite end portions of the gate electrode structure, and the gate electrode structure may not be entirely divided by the seventh openings 510.

A second division layer may be formed on the second blocking layer to fill the sixth and seventh openings 500 and 510, and may be planarized until the upper surface of the fifth insulating interlayer 490 is exposed. Accordingly, the second blocking layer may be transformed into a second blocking pattern 550, and the second division layer may be divided into second and third division patterns 570 and 580 filling the sixth and seventh openings 500 and 510, respectively.

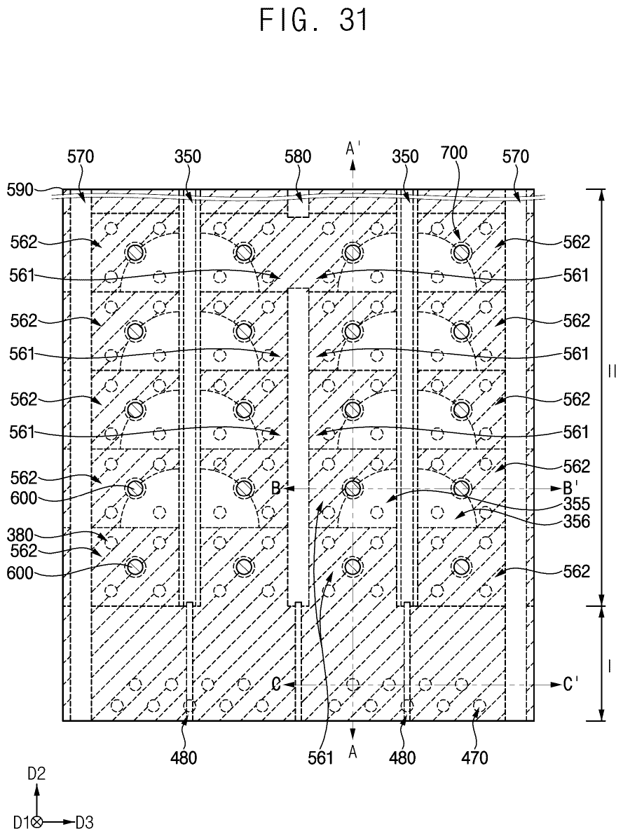

In FIGS. 31 to 34, a sixth insulating interlayer 590 may be formed on the fifth insulating interlayer 490, the second and third division patterns 570 and 580 and the second blocking pattern 550, and the fourth to sixth insulating interlayers 390, 490 and 590 may be partially removed to expose an upper surface of the eighth sacrificial pattern 370, and the exposed eighth sacrificial pattern 370 may be removed to form the second hole again.

A portion of the first insulation pattern 700 exposed by the second hole, a portion of the second insulating interlayer 190 thereunder, and a sidewall of the second blocking pattern 550 may be removed to enlarge the second hole. Accordingly, sidewalls of the first and second gate electrodes 561 and 562 and an upper surface of the second wiring 180 may be exposed by the second hole.

A second contact plug 600 may be formed in the enlarged second hole.

In FIGS. 1 to 6, a seventh insulating interlayer 610 may be formed on the sixth insulating interlayer 590 and the second contact plug 600, and a second via 620 extending through the seventh insulating interlayer 610 to contact an upper surface of the second contact plug 600 and a third via extending through the fifth to seventh insulating interlayers 490, 590, and 610 to contact an upper surface of the capping pattern 460 may be formed.

An eighth insulating interlayer 640 may be formed on the seventh insulating interlayer 610 and the second and third vias 620 and 630, and third and fourth wirings 650 and 660 extending through the eighth insulating interlayer 640 to contact upper surfaces of the second and third vias 620 and 630 may be formed to complete the fabrication of the semiconductor device.

For example, the second hole for forming the second contact plug 600 extending through the gate electrode structure may be formed, a portion of the fourth sacrificial layer 280 adjacent to the second hole may be removed by an etching process to form a recess, and an insulation pattern may be formed in the recess so that the second contact plug 600 may be electrically insulated from the first and second gate electrodes 561 and 562 at undesired levels. However, in this case, the etching process may not be properly controlled so that the second contact plug 600 may not be electrically insulated from the first and second gate electrodes 561 and 562 at the undesired levels.

Additionally, a thickness of the portion of the fourth sacrificial layer 280 through which the second hole extends has to be increased so that the second contact plug 600 may be electrically connected to the first and second gate electrodes 561 and 562 at desired levels.

However, in some implementations, before forming the second hole, the fourth opening 340 may be formed through the gate electrode structure on the second region II of the first substrate 100, the fifth and sixth sacrificial layers 281 and 282 may be partially removed through the fourth opening 340 to form the second to fourth recesses, and the fourth to sixth insulation patterns 353, 355, and 356 may be formed in the second to fourth recesses, respectively.

The second hold may be formed through the fifth sacrificial layer 281 or the sixth sacrificial layer 282 included in each of the step layer groups and the fourth insulation patterns 353 included in other ones of the step layer groups thereunder, and the second contact plug 600 that may be formed in the second hole may contact only one of the first and second gate electrodes 561 and 562 at a desired level.

Each of the fourth insulation patterns 353 may be formed by removing portions of the fifth and sixth sacrificial layers 281 and 282 within a given distance from the fourth opening 340 so as to have a sufficient area. Accordingly, the electrical insulation between the second contact plug 600 and the first and second gate electrodes 561 and 562 at undesired levels may be enhanced.

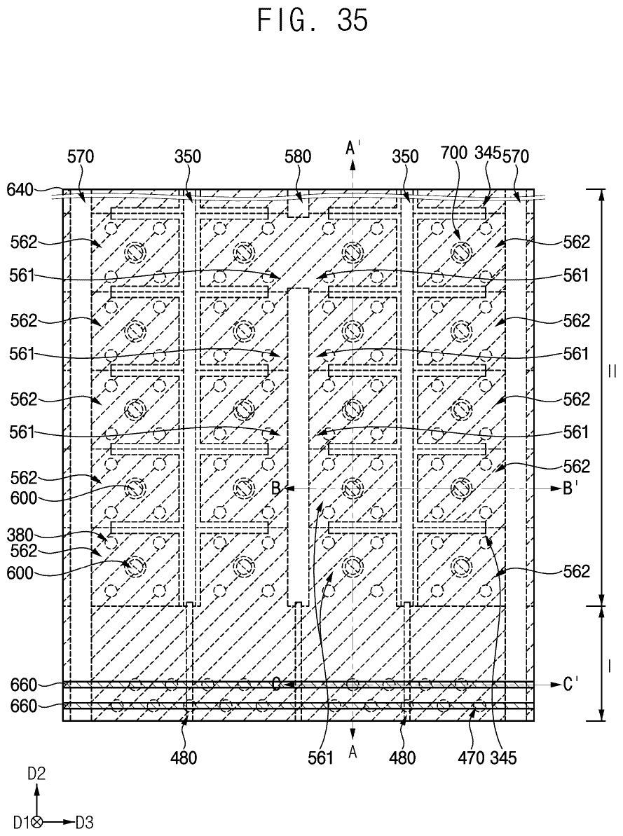

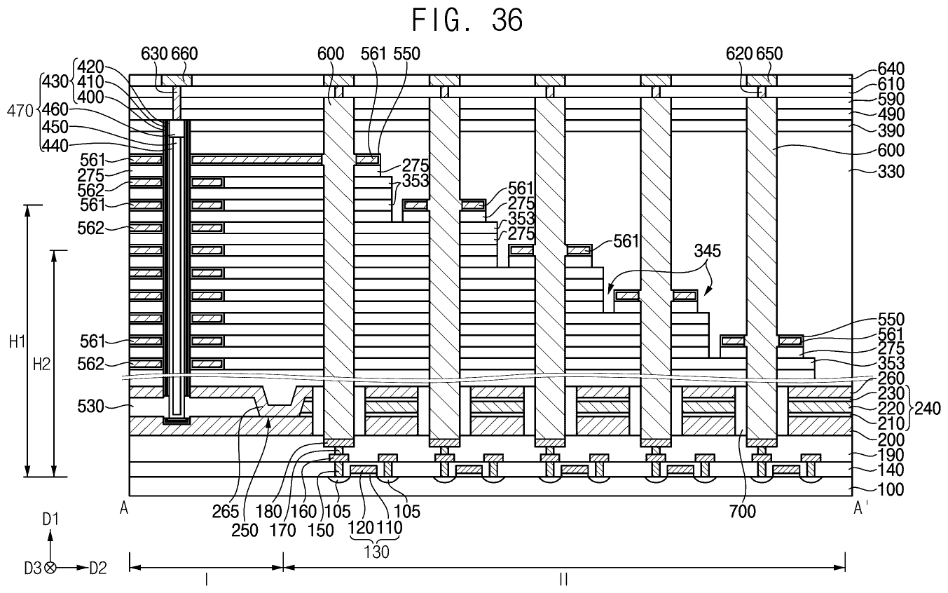

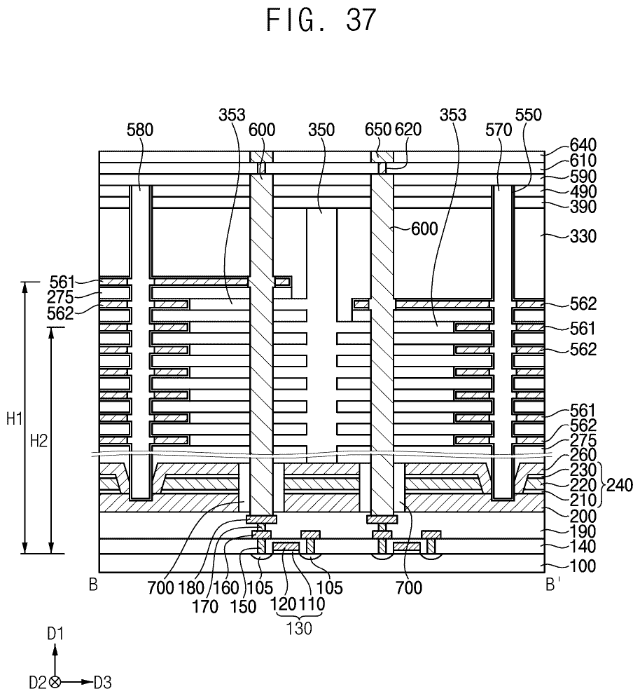

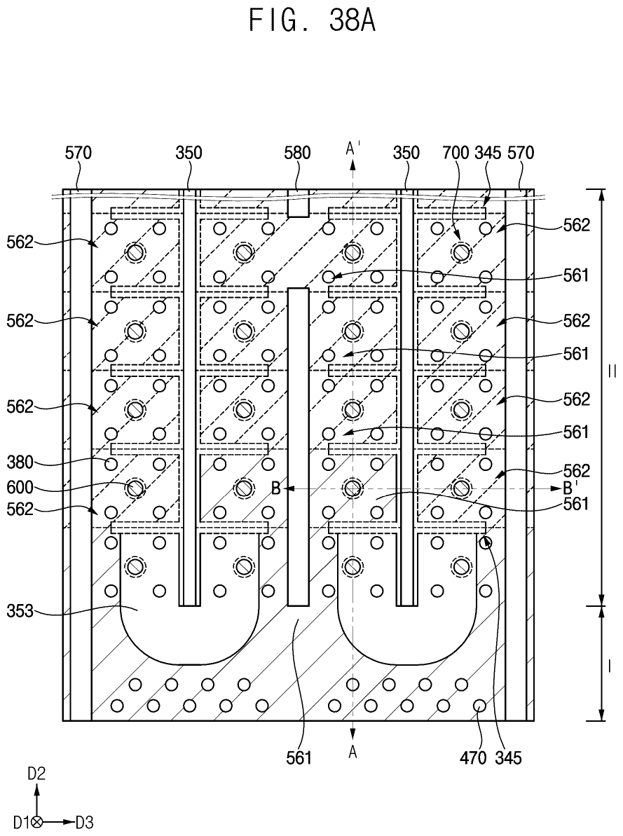

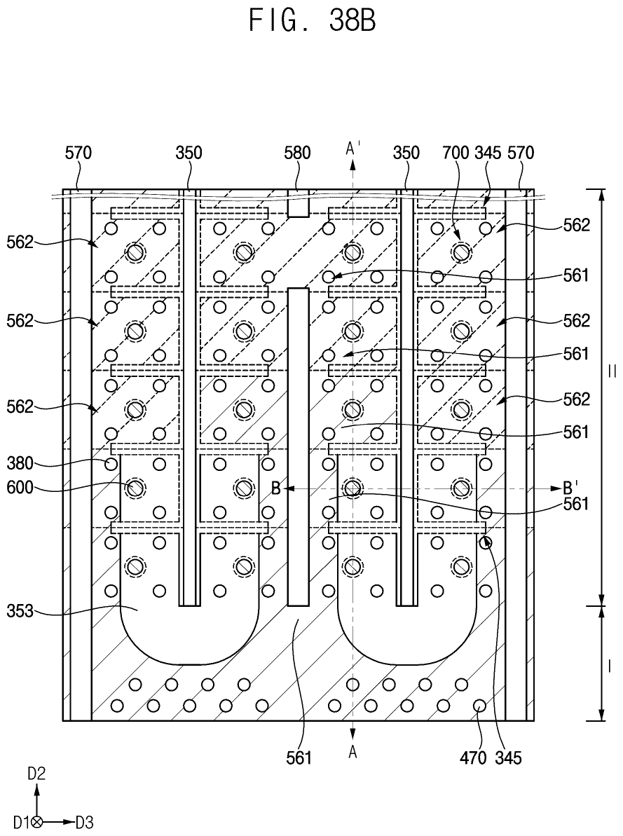

FIGS. 35 to 38 are a plan view and cross-sectional views illustrating an example of a semiconductor device in accordance with some implementations, which may correspond to FIGS. 2, 3, 4 and 6, respectively. The semiconductor device may be substantially the same as or similar to that of FIGS. 1 to 6, except for some elements, and thus repeated explanations are omitted herein.

In FIGS. 35 to 38, in the gate electrode structure, a sixth recess 345 may be formed at an end portion in the second direction D2 of the first step layer included in each of the step layer groups and a portion of the first step layer included in each of the step layer groups that is adjacent to an end portion in the second direction D2 of a step layer group directly over each of the step layer groups.

As described below, the fifth and sixth insulation patterns 355 and 345 at the same levels as and adjacent to the first and second gate electrodes 561 and 562, respectively, in each of the step layer groups may not be formed.

Additionally, the second contact plug 600 may be entirely surrounded (unbounded) by a corresponding one of the first and second gate electrodes 561 and 562 in each of the step layer groups.

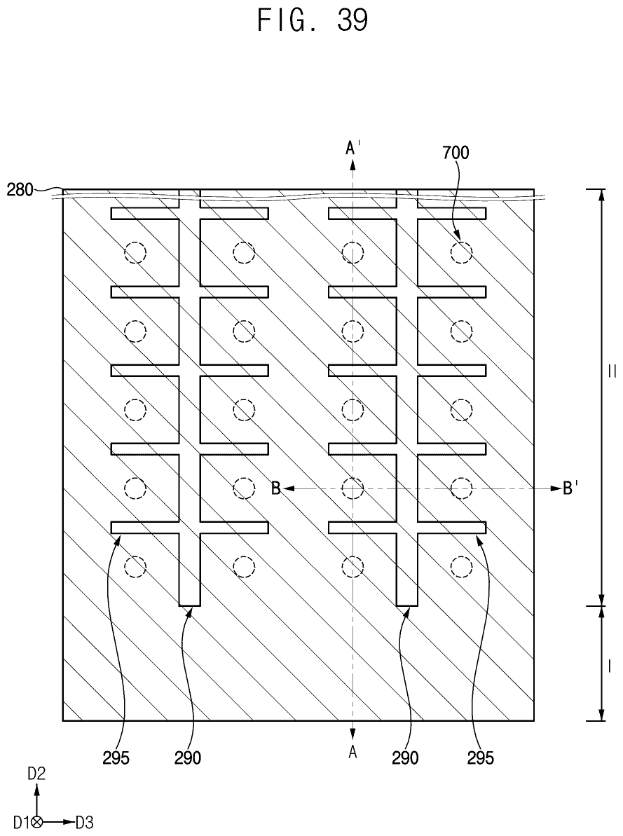

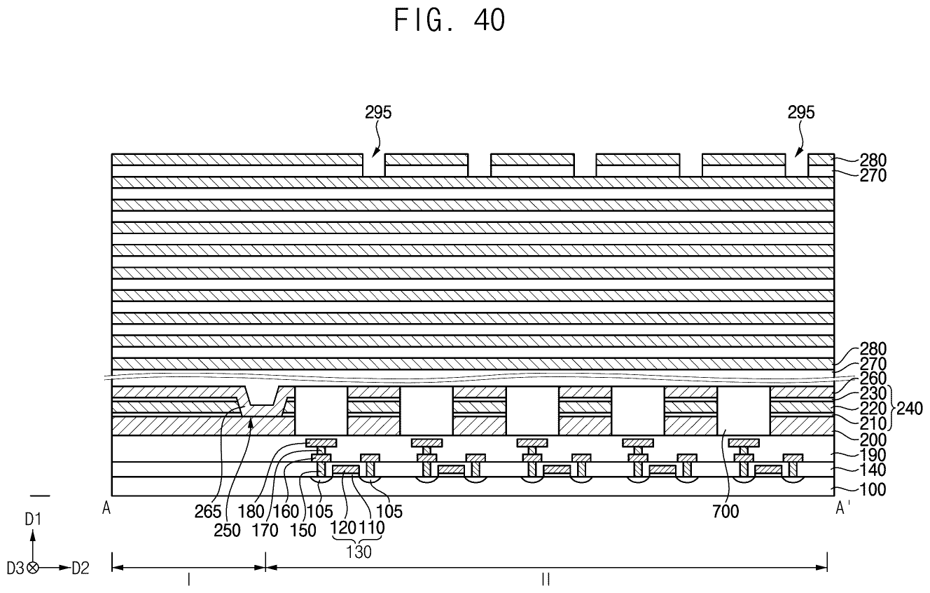

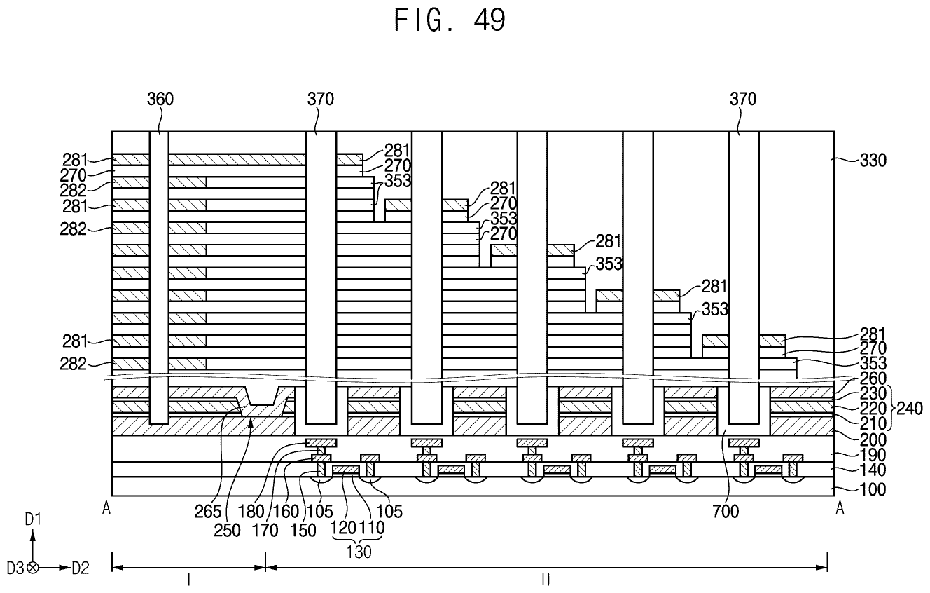

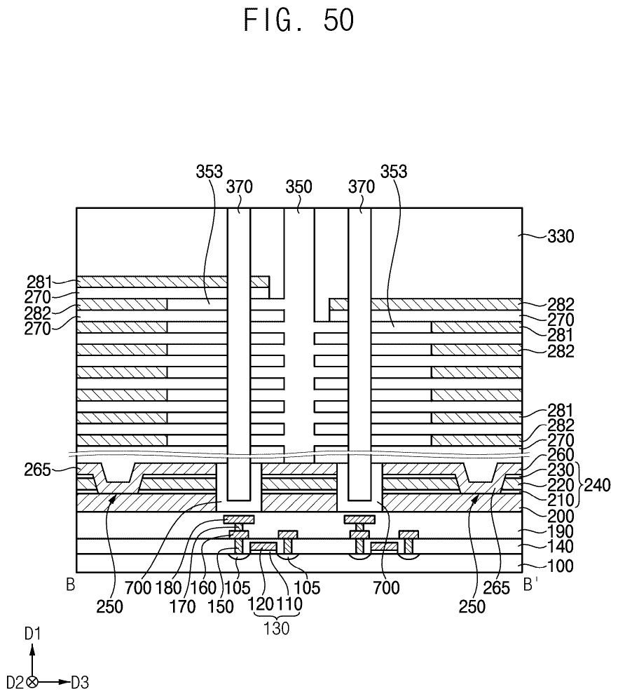

FIGS. 39 to 50 are plan views and cross-sectional views illustrating an example of a method of manufacturing a semiconductor device in accordance with some implementations. Particularly, FIGS. 39, 41, 44 and 48 are plan views, and FIGS. 40, 42-43, 45-47 and 49-50 are cross-sectional views.

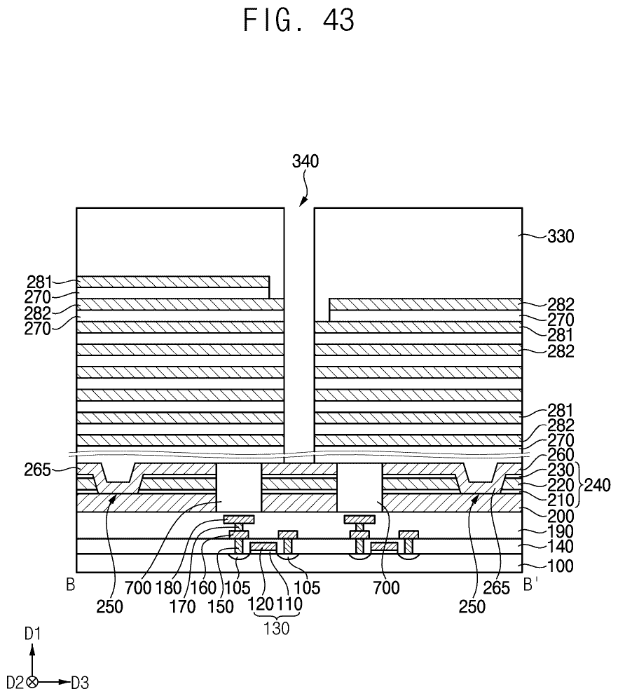

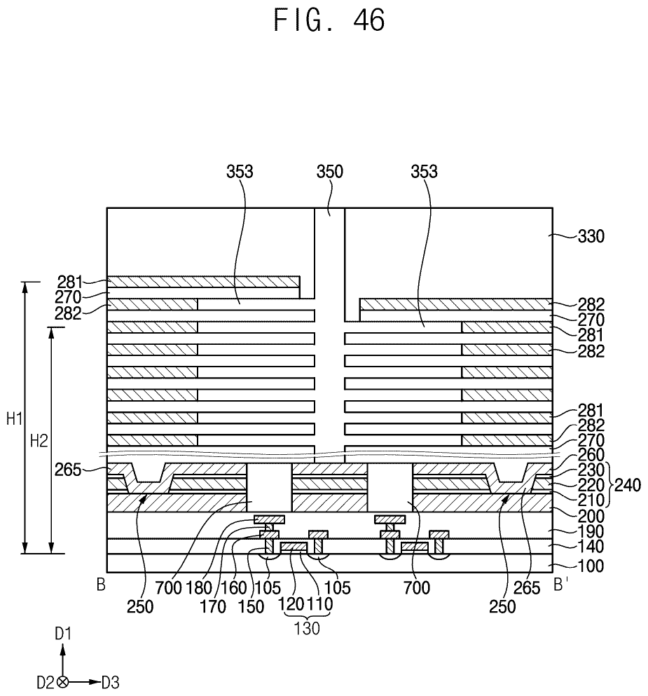

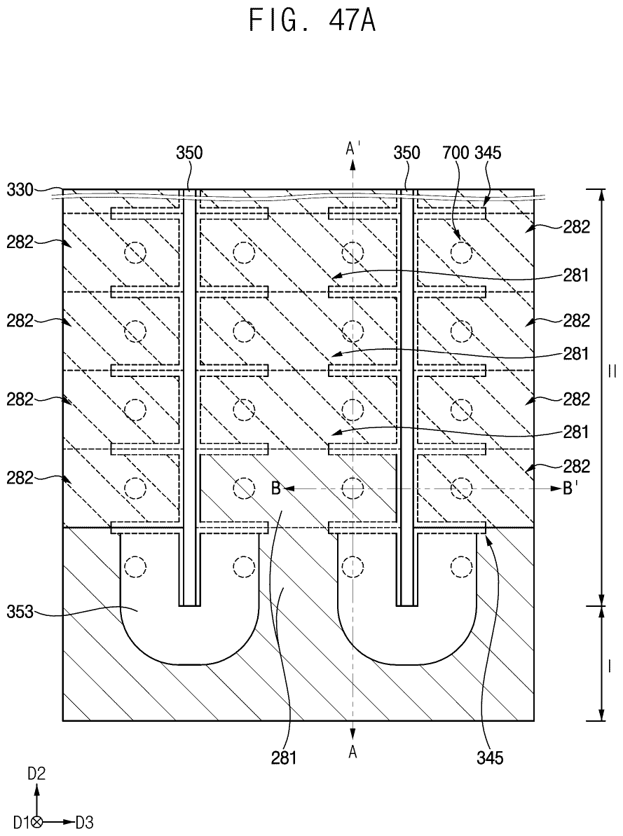

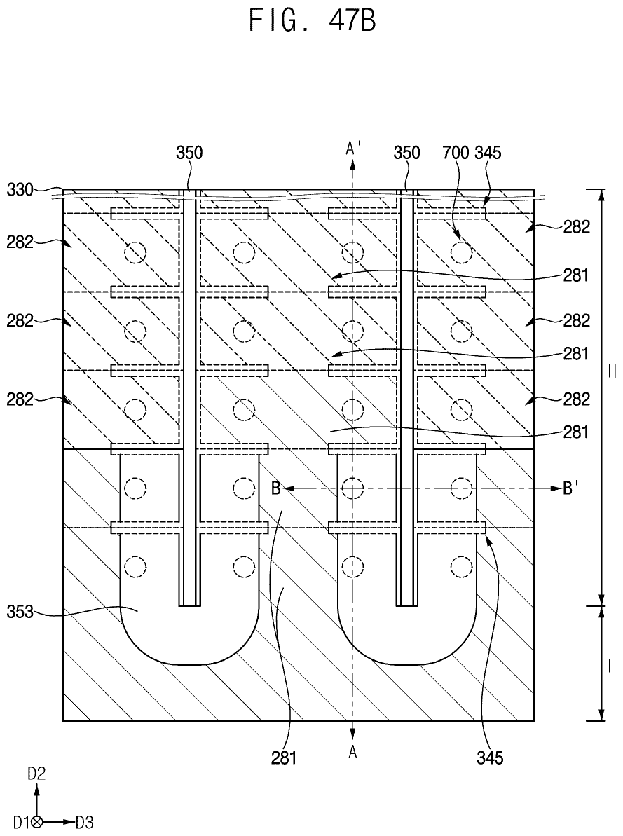

FIGS. 40, 42, 45 and 49 are vertical cross-sectional views taken along lines A-A′ of corresponding plan views, FIGS. 43, 46 and 50 are vertical cross-sectional views taken along lines B-B′ of corresponding plan views, FIG. 47A is a horizontal cross-sectional view at a height H1 of FIGS. 45 and 46, and FIG. 47B is a horizontal cross-sectional view at a height H2 of FIGS. 45 and 46.

The method of manufacturing the semiconductor device may include processes substantially the same as or similar to those illustrated with respect to FIGS. 7 to 34 and FIGS. 1 to 6, and the repeated explanations thereof are omitted herein.

In FIGS. 39 and 40, processes substantially the same as or similar to those illustrated with respect to FIGS. 7 to 9 may be performed.

However, in addition to the second opening 290 extending in the second direction D2 on the second region II of the first substrate 100 that may be formed by partially removing the uppermost one of the fourth sacrificial layers 280 and the uppermost one of the second insulation layer 270, an eighth opening 295 may be further formed to extend in the third direction D3 by a given distance from each of opposite sidewalls in the third direction D3 of the second opening 290.

In some implementations, a plurality of eighth openings 295 may be formed to be spaced apart from each other in the second direction D2 on the second region II of the first substrate 100, and may be formed at an area corresponding to an end portion in the second direction D2 in each of step layer groups and a portion of one of the step layer groups thereunder that is adjacent to the end portion in each of the step layer groups in the second direction D2.

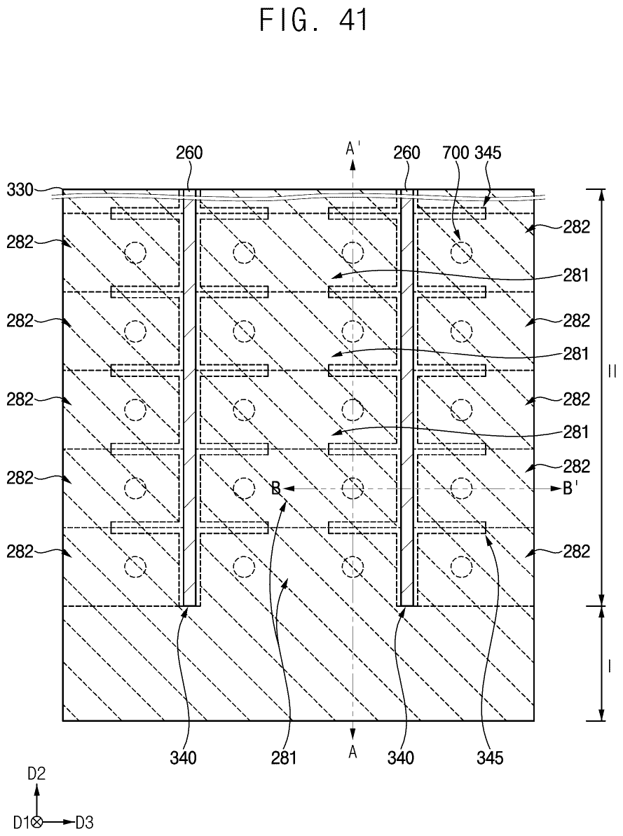

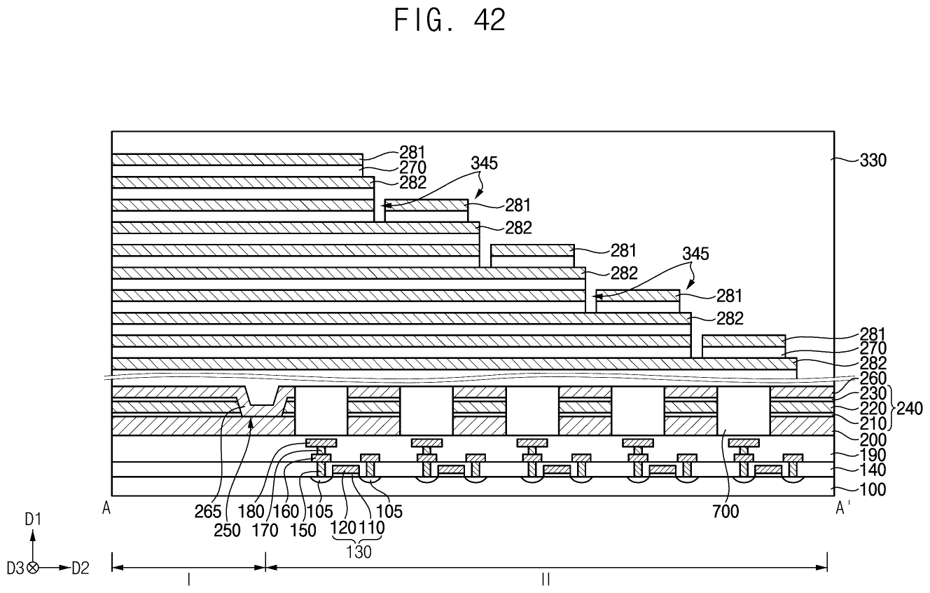

In FIGS. 41 to 43, processes substantially the same as or similar to those illustrated with respect to FIGS. 10 to 15 may be performed. Accordingly, a mold having a staircase structure may be formed, the third insulating interlayer 330 may be formed on the CSP 200 to cover the mold, and the fourth opening 340 may be formed partially through the third insulating interlayer 330 and the mold to expose an upper surface of the support layer 260. In the staircase structure, the sixth recess 345 may be formed at an end portion in the second direction D2 of the first step layer in each of the step layer groups and a portion of the first step layer in each of the step layer groups adjacent to an end portion in the second direction D2 of one of the step layer groups thereover.

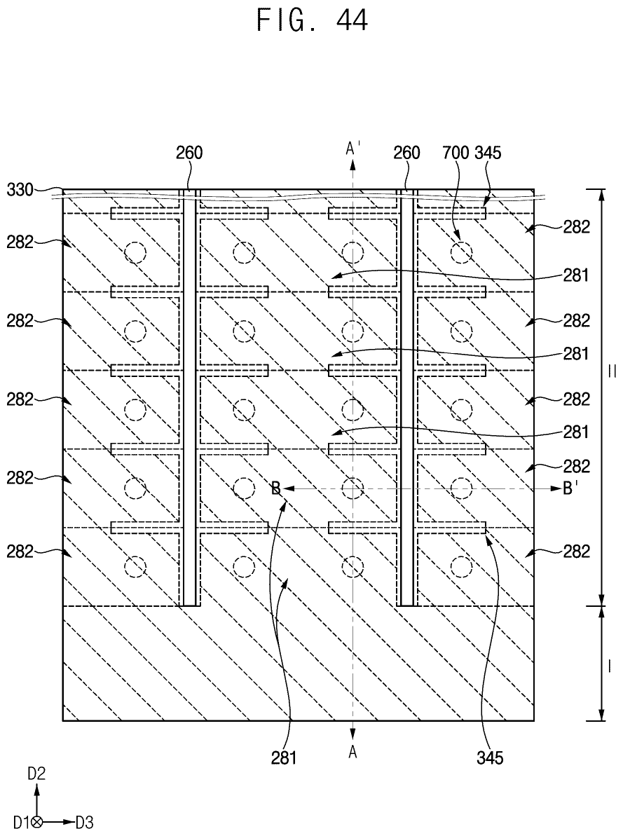

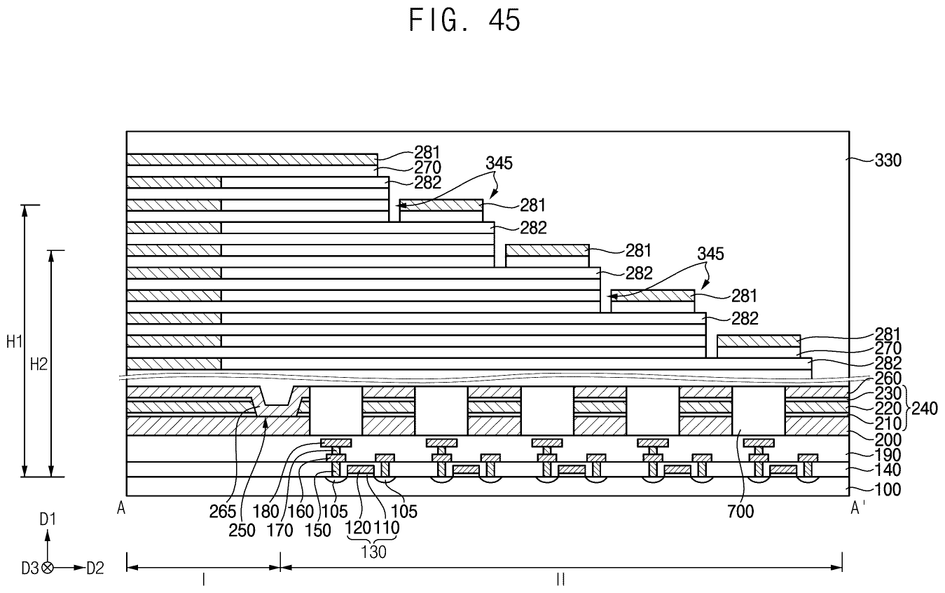

In FIGS. 44 to 47, processes substantially the same as or similar to those illustrated with respect to FIGS. 16 to 19 may be performed so that the fourth insulation pattern 353 may be formed in the second recess. However, the sixth recess 345 is formed at a portion of the first step layer in each of the step layer groups that is adjacent to the fourth opening 340, and a path for removing the fifth and sixth sacrificial layers 281 and 282 may be blocked from a portion of the fourth opening 340 that overlaps in the first direction D1 a portion of the fourth opening extending through one of the step layer groups over each of the step layer groups and is disposed at the same level as each of the step layer groups. Accordingly, the third and fourth recesses may not be formed, and the fifth and sixth insulation patterns 355 and 356 may not be formed.

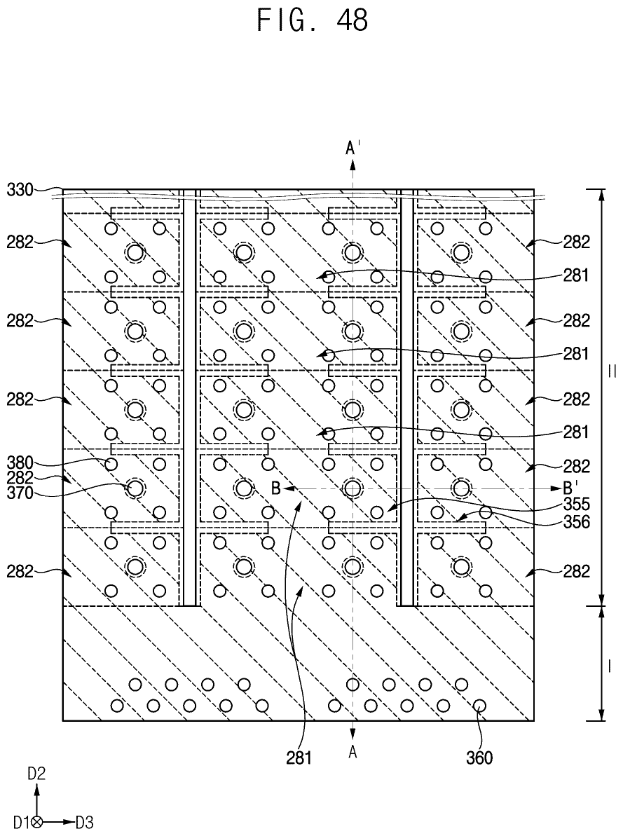

In FIGS. 48 to 50, processes substantially the same as or similar to those illustrated with respect to FIGS. 20 to 22 may be performed to form the seventh to ninth sacrificial patterns 360, 370, and 380. However, in some implementations, the eighth sacrificial pattern 370 may extend through the fifth sacrificial layer 281 of the first step of the first step layer included in each of other ones of the step layer group except for an uppermost one of the step layer groups to extend through the second insulation layers 270 and the fourth insulation patterns 353 thereunder, or may extend through the sixth sacrificial layer 282 of the second step of the second step layer included in the other ones of the step layer groups to extend through the second insulation layers 270 and the fourth insulation patterns 353 thereunder.

Some of the ninth sacrificial patterns 380 may extend through the fifth sacrificial layer 281 of the first step of the first step layer or the sixth sacrificial layer 282 of the second step of the second step layer included in each of the other ones of the step layer group except for the uppermost one of the step layer groups or to extend through the second insulation layers 270 and the fourth insulation patterns 353 thereunder. Additionally, some of the ninth sacrificial patterns 380 may extend through the fifth sacrificial layer 281 of the first step of the first step layer or the sixth sacrificial layer 282 of the second step of the second step layer included in each of the other ones of the step layer group except for the uppermost one of the step layer groups or to extend through the second insulation layers 270 and the fifth and sixth sacrificial layers 281 and 282 thereunder.

In FIGS. 35 to 38, processes substantially the same as or similar to those illustrated with respect to FIGS. 23 to 34 and FIGS. 1 to 6 may be performed to complete the fabrication of the semiconductor device.

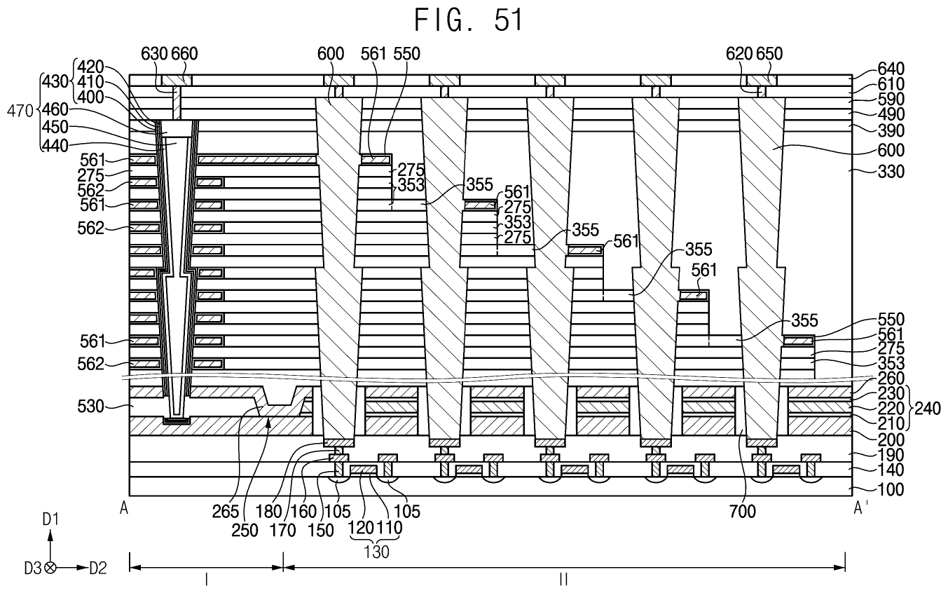

FIG. 51 is a cross-sectional view illustrating an example of a semiconductor device in accordance with some implementations, which may correspond to FIG. 3. The semiconductor device may be substantially the same as or similar to that of FIGS. 1 to 6, except for shapes of the memory channel structure 470, the support structure 380 and the second contact plug 600.

In FIG. 51, each of the memory channel structure 470, the support structure 380, and the second contact plug 600 may have a lower portion and an upper portion sequentially stacked, and each of the lower and upper portions may have a width gradually decreasing from a top toward a bottom thereof in the first direction D1. In some implementations, an upper surface of the lower portion may have a width greater than a width of a lower surface of the upper portion in each of the memory channel structure 470, the support structure 380 and the second contact plug 600.

FIG. 51 shows that each of the memory channel structure 470, the support structure 380, and the second contact plug 600 includes two portions, that is, the lower and upper portions. However, the present disclosure may not be limited thereto, and may include more than two portions. Each of the portions may have a width gradually decreasing from a top toward a bottom thereof, and a width of an upper surface of a portion that is disposed at a relatively low level may be greater than a width of a lower surface of a portion that is disposed at a relatively high level.

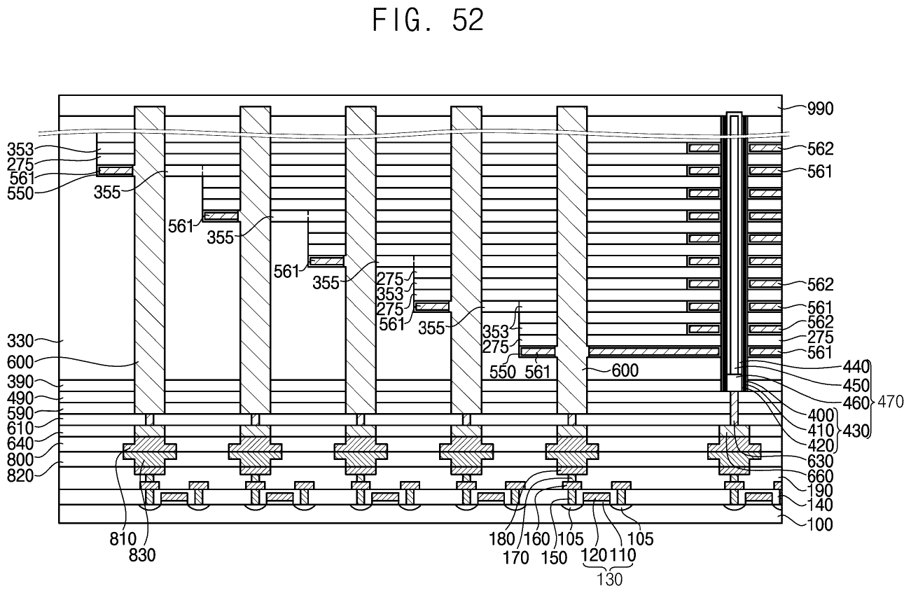

FIG. 52 is a cross-sectional view illustrating an example of a semiconductor device in accordance with some implementations, which may correspond to FIG. 3. The semiconductor device may be substantially the same as or similar to that of FIGS. 1 to 6 except for some elements.

In FIG. 51, the semiconductor device may be manufactured by inverting the semiconductor device of FIGS. 1 to 6, so that lower and upper portions of each structure in the semiconductor device in FIG. 51 may correspond to upper and lower portions, respectively, of each structure in the semiconductor device in FIGS. 1 to 6.

In FIG. 52, an upper surface of each of the memory channel structure 470 and the support structure 380 may extend through a lower portion of a second substrate 990, and an upper surface and an upper sidewall of the channel 440 may not be covered by the charge storage structure 430, but may contact the second substrate 990.

The second substrate 990 may include a semiconductor material, e.g., silicon, germanium, silicon-germanium, etc., and n-type or p-type impurities may be doped into a portion or an entire portion of the second substrate 990 so that the portion of the second substrate 990 may serve as a common source line.

A second bonding layer 820 and a first bonding layer 800 may be sequentially stacked in the first direction D1 between the second insulating interlayer 190 and the eighth insulating interlayer 640, and a second bonding pattern 830 and a first bonding pattern 810 may be formed in the second bonding layer 820 and the first bonding layer 800, respectively, to contact each other. The first bonding pattern 810 may contact each of the third and fourth wirings 650 and 660, and the second bonding pattern 830 may contact the second wiring 180.

Each of the first and second bonding layers 800 and 820 may include an insulating material, e.g., silicon carbonitride, and each of the first and second bonding patterns 810 and 830 may include a conductive material, e.g., copper.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a substrate;
a gate electrode structure on the substrate, the gate electrode structure including a plurality of gate electrodes spaced apart from each other in a first direction substantially perpendicular to an upper surface of the substrate, wherein each gate electrode of the plurality of gate electrodes extends in a second direction substantially parallel to the upper surface of the substrate;
a memory channel structure extending through the gate electrode structure on the substrate; and
a first contact plug extending in the first direction on the substrate,
wherein the first contact plug extends through and contacts a corresponding one of the plurality of gate electrodes, and
wherein a portion of a sidewall of the first contact plug that is at substantially a same level as a corresponding one of the plurality of gate electrodes is unbounded by the corresponding one of the plurality of gate electrodes.

2. The semiconductor device according to claim 1,
wherein a portion of a sidewall of the corresponding one of the plurality of gate electrodes has a quadrant shape in a plan view, and
wherein the first contact plug contacts the portion of the sidewall of the corresponding one of the plurality of gate electrodes.

3. The semiconductor device according to claim 2, further comprising an insulation pattern adjacent to the portion of the sidewall of the corresponding one of the plurality of gate electrodes,
wherein the insulation pattern is at substantially the same level as the portion of the sidewall of the corresponding one of the gate electrodes, and
wherein the first contact plug extends through and contacts the portion of the sidewall of the corresponding one of the plurality of gate electrodes and the insulation pattern.

4. The semiconductor device according to claim 1,
wherein the gate electrode structure includes a plurality of gate electrode groups arranged in the first direction, and wherein each gate electrode group comprises a different set of adjacent gate electrodes of the plurality of gate electrodes
wherein, for each gate electrode group of the plurality of gate electrode groups, adjacent gate electrodes of the gate electrode group have substantially the same lengths in the second direction, and
wherein, from an uppermost level toward a lowermost level, lengths of the adjacent gate electrodes in the second direction increase between gate electrode groups of the plurality of gate electrode groups.

5. The semiconductor device according to claim 4,
wherein each gate electrode group of the plurality of gate electrode groups includes an even number of the adjacent gate electrodes stacked in the first direction, and
wherein end portions in the second direction of the adjacent gate electrodes are disposed in a third direction substantially parallel to the upper surface of the substrate and crossing the second direction to form respective steps.

6. The semiconductor device according to claim 5,
wherein each gate electrode group of the plurality of gate electrode groups includes a first gate electrode and a second gate electrode stacked in the first direction,
wherein a sidewall of an end portion in the second direction of the first gate electrode has a first quadrant shape in a plan view,
wherein a sidewall of an end portion in the second direction of the second gate electrode has a second quadrant shape in a plan view, and
wherein the first quadrant shape and the second quadrant shape are symmetrical with respect to a straight line extending in the second direction in a plan view.

7. The semiconductor device according to claim 6, further comprising a plurality of first contact plugs,
wherein each first contact plug of the plurality of first contact plugs contacts the sidewall of the end portion of the first gate electrode having the first quadrant shape or the sidewall of the end portion of the second gate electrode having the second quadrant shape.

8. The semiconductor device according to claim 1, further comprising a second contact plug extending through an uppermost one of the plurality of gate electrodes,
wherein a sidewall of a portion of the second contact plug at substantially the same level as the uppermost one of the gate electrodes is entirely surrounded by the uppermost one of the gate electrodes.

9. The semiconductor device according to claim 1, wherein a thickness in the first direction of each gate electrode of the plurality of gate electrodes is substantially constant.

10. The semiconductor device according to claim 1, wherein the plurality of gate electrodes have substantially the same thicknesses in the first direction.

11. A semiconductor device comprising:
a substrate;
a gate electrode structure on the substrate, the gate electrode structure including a plurality of gate electrodes spaced apart from each other in a first direction substantially perpendicular to an upper surface of the substrate, wherein each gate electrode of the plurality of gate electrodes extends in a second direction substantially parallel to the upper surface of the substrate;
a plurality of insulation patterns, each insulation pattern being at substantially the same level as a respective one of the plurality of gate electrodes, and each insulation pattern being adjacent to sidewalls of end portions in the second direction of a respective gate electrode of the plurality of gate electrodes;
a memory channel structure extending through the gate electrode structure on the substrate; and
a contact plug extending in the first direction on the substrate,
wherein the contact plug extends through and contacts at least a portion of a corresponding one of the plurality of gate electrodes and an insulating pattern of the plurality of insulation patterns at a respective level being lower than a level of a corresponding one of the plurality of gate electrodes, and
wherein an end portion in the second direction of each of the plurality of insulation patterns includes a sidewall having a U shape in a plan view.

12. The semiconductor device according to claim 11,
wherein the substrate includes a first region and a second region,
wherein the memory channel structure is disposed on the first region of the substrate, and the contact plug is disposed on the second region of the substrate, and
wherein the end portion in the second direction of each of the plurality of insulation patterns is disposed on the first region of the substrate.

13. The semiconductor device according to claim 11,
wherein the gate electrode structure includes a plurality of gate electrode groups arranged in the first direction, wherein each gate electrode group of the plurality of gate electrode groups comprises a different set of adjacent gate electrodes from the plurality of gate electrodes,
wherein, for each gate electrode group of the plurality of gate electrode groups, adjacent gate electrodes of the gate electrode group have substantially the same lengths in the second direction, and
wherein, from an uppermost level toward a lowermost level, lengths of the adjacent gate electrodes in the second direction increase between gate electrode groups of the plurality of gate electrode groups.

14. The semiconductor device according to claim 13,
wherein each gate electrode group of the plurality of gate electrode groups includes an even number of the adjacent gate electrodes stacked in the first direction, and
wherein end portions in the second direction of the adjacent gate electrodes are disposed in a third direction substantially parallel to the upper surface of the substrate and crossing the second direction to form respective steps.

15. The semiconductor device according to claim 14,
wherein each gate electrode group of the plurality of gate electrode groups includes a first gate electrode and a second gate electrode stacked in the first direction,
wherein a sidewall of an end portion in the second direction of the first gate electrode has a first quadrant shape in a plan view,
wherein a sidewall of an end portion in the second direction of the second gate electrode has a second quadrant shape in a plan view, and
wherein the first quadrant shape and the second quadrant shape are symmetrical with respect to a straight line extending in the second direction in a plan view.

16. The semiconductor device according to claim 15, further comprising a plurality of contact plugs,
wherein each first contact plug of the plurality of contact plugs contacts the sidewall of the end portion of the first gate electrode having the first quadrant shape or the sidewall of the end portion of the second gate electrode having the second quadrant shape.

17. The semiconductor device according to claim 11, wherein a sidewall of a portion of the contact plug at substantially the same level as the corresponding one of the plurality of gate electrodes is entirely surrounded by the corresponding one of the plurality of gate electrodes.

18. A semiconductor device comprising:
a substrate having a first region and a second region;
a lower circuit pattern on the first region and the second region of the substrate;
a common source plate (CSP) over the lower circuit pattern;
a gate electrode structure on the CSP, the gate electrode structure including a plurality of gate electrodes spaced apart from each other in a first direction substantially perpendicular to an upper surface of the substrate, wherein each gate electrode of the plurality of gate electrodes extends in a second direction substantially parallel to the upper surface of the substrate;
a memory channel structure on the CSP, the memory channel structure extending through the gate electrode structure on the first region of the substrate;
a first insulation pattern on the CSP, the first insulation pattern extending through the gate electrode structure in the second direction on the second region of the substrate;
a plurality of second insulation patterns, each insulation pattern being at substantially the same levels as a respective one of the plurality of gate electrodes, and each second insulation pattern being adjacent to sidewalls of end portions in the second direction of a respective gate electrode of the plurality of gate electrodes; and
a contact plug extending in the first direction on the second region of the substrate,
wherein the contact plug extends through and contacts a corresponding one of the plurality of gate electrodes, and
wherein a portion of a sidewall of the contact plug at substantially the same level as the corresponding one of the plurality of gate electrodes is unbounded by the corresponding one of the plurality of gate electrodes.

19. The semiconductor device according to claim 18, further comprising a third insulation pattern at substantially the same level as the corresponding one of the plurality of gate electrodes,
wherein the third insulation pattern surrounds the portion of the sidewall of the contact plug.

20. The semiconductor device according to claim 18,
wherein the contact plug extends into the CSP, and
wherein the contact plug is electrically connected to the lower circuit pattern.
